(19) United States
(12) Patent Application Publication
(10) Pub. No.: US 2019/0043636 A1
(43) Pub. Date: Feb. 7, 2019

(54) SYSTEM AND METHOD FOR CHARACTERIZING CONDUCTIVE MATERIALS

(71) Applicant: University of Virginia Patent Foundation, Charlottesville, VA (US)

(72) Inventors: Gary M. Koenig, JR., Charlottesville, VA (US); Zhaoxiang Qi, Charlottesville, VA (US)

(21) Appl. No.: 15/815,195

(22) Filed: Nov. 16, 2017

Related U.S. Application Data
(60) Provisional application No. 62/540,144, filed on Aug. 2, 2017.

(51) Int. Cl. H01B 1/20; H01B 1/14; G01R 31/30; C01D 15/00; H01M 10/052

(52) U.S. Cl. CPC H01B 1/20; H01B 1/14; H01M 4/02; C01D 15/00; H01M 10/052; G01R 31/3004

(57) ABSTRACT

Methods and systems for rapidly characterizing electrochemically active particle dispersions are provided. In various embodiments, the methods and systems advantageously reduce the system complexity to identify what fraction of a cell resistance may be due to the active material.

### CROSS-REFERENCE TO RELATED APPLICATION

This application claims the benefit of priority to U.S. Provisional Patent Application Ser. No. 62/540,144 entitled “Dispersion Particle Resistance (DPR) for Characterization and Quality Control of Battery Materials and Related Method Thereof,” filed Aug. 2, 2017, which is incorporated by reference herein in its entirety.

### STATEMENT OF GOVERNMENT SUPPORT

This invention was made with Government support under Grant No. ECCS 1405134 awarded by National Science Foundation. The U.S. Government has certain rights in this invention.

### BACKGROUND

Battery active materials are evaluated using numerous material characterization techniques for fundamental understanding, comparative analysis during research and development, and for quality control during manufacturing. Electrochemical properties of the active materials also need to be investigated and validated, and this analysis is very time and material intensive generally requiring electrode fabrication, cell assembly and cell cycling. In addition, evaluating active materials electrochemically in battery cells can be complicated by the electrode microstructure and the contributions of other components within the cell that are not the active materials.

### SUMMARY OF THE INVENTION

In various embodiments, a method of characterizing a dispersion includes electrically applying an excitation signal to the dispersion and measuring an electrical response elicited by the excitation signal. The dispersion includes electrically and/or ionically conductive particles and a liquid carrier; and the particles are mechanically perturbed.

In various embodiments, a method of characterizing a dispersion includes electrically applying an excitation signal to the dispersion; and measuring an electrical response elicited by the excitation signal. The dispersion includes electrically conductive particles of a lithium-ion conducting material and an aqueous electrolyte; and the particles are mechanically perturbed by flowing the dispersion including the particles through an electrochemical cell that includes a channel.

In various embodiments, a system for characterizing a dispersion includes an anode, a cathode, an electrolyte; and a dispersion that includes electrically conductive particles and a liquid carrier. In various embodiments, the system includes any suitable reference electrode described herein.

Advantageously, in various embodiments, the method can measure the resistance of electroactive particles in which the primary contribution to the resistance results from the particles themselves. Advantageously, in various embodiments, the measurements of the method can be completed on timescale three orders of magnitude less than the coin cell validation of the aging impact on rate capability.

### BRIEF DESCRIPTION OF THE FIGURES

The drawings illustrate generally, by way of example, but not by way of limitation, various embodiments of the present invention.

FIG. 1 is an illustration of an electrochemical cell, in accordance with various embodiments.

FIGS. 2A-2F are a series of voltage profiles during constant current discharge for six LiFePO₄ (LFP) materials, in accordance with various embodiments. For all plots, the discharge curves correspond, going from right to left, to 0.1 C, 0.5 C, 1 C, 2 C, and 5 C, respectively. C rates were based on the gravimetric capacity of the material at 0.1 C.

FIG. 3 is a plot of discharge capacities relative to the discharge capacity at 0.1 C for six LFP materials, in accordance with various embodiments.

FIG. 4A is a chronoamperometry plot for 2 vol % LFP-3 using incremental voltage step up from 0.230 V to 0.242 V (vs. Ag/AgCl reference electrode), in accordance with various embodiments.

FIG. 4B is a plot of the extracted potential vs. current data set used to determine the dispersion particle resistance (DPR) of 2 vol % LFP-3, in accordance with various embodiments.

FIG. 5A is a plot of DPR (dispersion particle resistance) vs. volumetric loading of LFP-1, in accordance with various embodiments.

FIG. 5B is the DPR of LFP-1 to LFP-6 measured at 2 vol % for each material, in accordance with various embodiments. Error bars represent the standard deviations of three measurements for each sample.

FIG. 6 shows coin cell discharge capacity at different rates for pristine LFP-3 (squares) and LFP-3 aged in 1 M Li₂SO₄ (circles) for 15 days, in accordance with various embodiments.

FIG. 7 shows X-ray diffraction (XRD) patterns for LFP-1 to LFP-6 particles and for LFP-3 particles after aging for 15 days in 1 M Li₂SO₄, in accordance with various embodiments.

FIGS. 8A-8F show scanning electron micrograph (SEM) images of LFP-1 to LFP-6 particles, in accordance with various embodiments.

FIGS. 9A-9F show thermogravimetric analysis (TGA) profiles for LFP-1 to LFP-6 particles, in accordance with various embodiments.

FIGS. 10A-10C show the charge/discharge profile for the 4^{th} cycle of LFP-3, LFP-4, and LFP-5 electrodes fabricated without any additional conductive additive, in accordance with various embodiments.

FIG. 11 is an illustration of an electrochemical cell, in accordance with various embodiments.

FIGS. 12A-12C show constant current discharge profiles at increasing C-rates for Li₄Ti₅O₁₂ (LTO) materials identified by labels LTO-1, LTO-2, and LTO-3, respectively, in accordance with various embodiments.

FIG. 12D shows the discharge capacity of LTO-1 to LTO-3 particles (circles: LTO-1; triangles: LTO-2; diamonds: LTO-3) at different C-rates relative to the capacities at 0.1 C, in accordance with various embodiments.

FIG. 13 is a plot of potential at a capacity of 25 mAh g⁻¹ at increasing current per mass of active material for LTO-3.

FIG. 14A is a plot of average potentials after reaching a steady plateau in the measured potential at increasing CP discharge currents for a 2 vol % suspension of LTO-2 dispersed in electrolyte.

FIG. 14B is a plot of DPR values determined from the slopes of all fitted lines for three LTO materials at three different loadings (circles: LTO-1; triangles: LTO-2; diamonds: LTO-3; error bars show the standard deviations of a series of three measurements).

FIGS. 15A-15C show a series of SEM images of LTO-1, LTO-2, and LTO-3 particles, respectively, in accordance with various embodiments.

FIG. 16 is a series of XRD diffraction patterns for LTO-1, LTO-2, and LTO-3 particles, in accordance with various embodiments.

FIG. 17 is a chronopotentiometry (CP) profile on a 0.5 vol % LTO-1 suspension at sequential steps in the discharge currents of 0.03, 0.04, 0.05 mA, in accordance with various embodiments.

FIG. 18 is a chronopotentiometry (CP) profile on LTO-free electrolyte at a discharge current of 0.02 mA, in accordance with various embodiments.

FIG. 19 shows the method of characterizing a dispersion, according to various embodiments.

### DETAILED DESCRIPTION OF THE INVENTION

Reference will now be made in detail to certain embodiments of the disclosed subject matter, examples of which are illustrated in part in the accompanying drawings. While the disclosed subject matter will be described in conjunction with the enumerated claims, it will be understood that the exemplified subject matter is not intended to limit the claims to the disclosed subject matter.

Throughout this document, values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “about 0.1% to about 5%” or “about 0.1% to 5%” should be interpreted to include not just about 0.1% to about 5%, but also the individual values (e.g., 1%, 2%, 3%, and 4%) and the sub-ranges (e.g., 0.1% to 0.5%, 1.1% to 2.2%, 3.3% to 4.4%) within the indicated range. The statement “about X to Y” has the same meaning as “about X to about Y,” unless indicated otherwise. Likewise, the statement “about X, Y, or about Z” has the same meaning as “about X, about Y, or about Z,” unless indicated otherwise.

In this document, the terms “a,” “an,” or “the” are used to include one or more than one unless the context clearly dictates otherwise. The term “or” is used to refer to a nonexclusive “or” unless otherwise indicated. The statement “at least one of A and B” or “at least one of A or B” has the same meaning as “A, B, or A and B.” In addition, it is to be understood that the phraseology or terminology employed herein, and not otherwise defined, is for the purpose of description only and not of limitation. Any use of section headings is intended to aid reading of the document and is not to be interpreted as limiting; information that is relevant to a section heading may occur within or outside of that particular section.

In the methods described herein, the acts can be carried out in any order without departing from the principles of the invention, except when a temporal or operational sequence is explicitly recited. Furthermore, specified acts can be carried out concurrently unless explicit claim language recites that they be carried out separately. For example, a claimed act of doing X and a claimed act of doing Y can be conducted simultaneously within a single operation, and the resulting process will fall within the literal scope of the claimed process.

The term “about” as used herein can allow for a degree of variability in a value or range, for example, within 10%, within 5%, or within 1% of a stated value or of a stated limit of a range, and includes the exact stated value or range.

The term “substantially” as used herein refers to a majority of, or mostly, as in at least about 50%, 60%, 70%, 80%, 90%, 95%, 96%, 97%, 98%, 99%, 99.5%, 99.9%, 99.99%, or at least about 99.999% or more, or 100%. The term “substantially free of” as used herein can mean having none or having a trivial amount of, such that the amount of material present does not affect the material properties of the composition including the material, such that the composition is about 0 wt % to about 5 wt % of the material, or about 0 wt % to about 1 wt %, or about 5 wt % or less, or less than, equal to, or greater than about 4.5 wt %, 4, 3.5, 3, 2.5, 2, 1.5, 1, 0.9, 0.8, 0.7, 0.6, 0.5, 0.4, 0.3, 0.2, 0.1, 0.01, or about 0.001 wt % or less. The term “substantially free of” can mean having a trivial amount of, such that a composition is about 0 wt % to about 5 wt % of the material, or about 0 wt % to about 1 wt %, or about 5 wt % or less, or less than, equal to, or greater than about 4.5 wt %, 4, 3.5, 3, 2.5, 2, 1.5, 1, 0.9, 0.8, 0.7, 0.6, 0.5, 0.4, 0.3, 0.2, 0.1, 0.01, or about 0.001 wt % or less, or about 0 wt %.

### Method of Characterizing a Dispersion

In various embodiments, a method of characterizing a dispersion includes electrically applying an excitation signal to the dispersion and measuring an electrical response elicited by the excitation signal. The dispersion includes electrically and/or ionically conductive particles and a liquid carrier; and the particles are mechanically perturbed.

The excitation can include a specified voltage or series of voltages applied to the dispersion and the electrical response includes a measured current. The excitation can also include a specified current or series of currents applied to the dispersion and the electrical response includes a measured voltage. The excitation signal can result in either oxidation or reduction of the electrically conductive particles in the dispersion. Thus, the current or voltage excitation can be induce oxidization or reduction of the conductive particles, depending on the composition of particles used.

Perturbing the particles can include agitating the particles in a vessel, such as an electrochemical cell. Perturbing or agitating the particles can include flowing the dispersion including the particles through an electrochemical cell that includes a channel. Flowing of the dispersion can include the flow of the dispersion through one or more channels in an electrochemical cell, which can be effected by any suitable means for moving fluids. For example, a peristaltic pump can be used to move the dispersion through one or more channels, and/or through fluid inlets and fluid outlets. In various embodiments, the particles are mechanically perturbed during the measuring or before the measuring.

Suitable flow rates for the dispersion can be about 5 mL/min to about 400 mL/min. In various embodiments, the flow rate for the dispersion can be about 5 mL/min to about 350 mL/min, about 5 mL/min to about 300 mL/min, about 5 mL/min to about 250 mL/min, about 5 mL/min to about 200 mL/min, about 5 mL/min to about 150 mL/min, about 5 mL/min to about 100 mL/min, about 10 mL/min to about 400 mL/min, about 20 mL/min to about 400 mL/min, about 5 mL/min to about 400 mL/min, about 5 mL/min to about 400 mL/min, about 50 mL/min to about 400 mL/min, about 75 mL/min to about 400 mL/min, about 100 mL/min to about 400 mL/min, about 150 mL/min to about 400 mL/min, or about 200 mL/min to about 400 mL/min. The flow rate of the dispersion can be about 5 mL/min, 25 mL/min, 45 mL/min, 65 mL/min, 85 mL/min, 105 mL/min, 125 mL/min, 145 mL/min, 165 mL/min, 185 mL/min, 205 mL/min, 225 mL/min, 245 mL/min, 265 mL/min, 285 mL/min, 305 mL/min, 325 mL/min, 345 mL/min, 365 mL/min, 385 mL/min, or 400 mL/min.

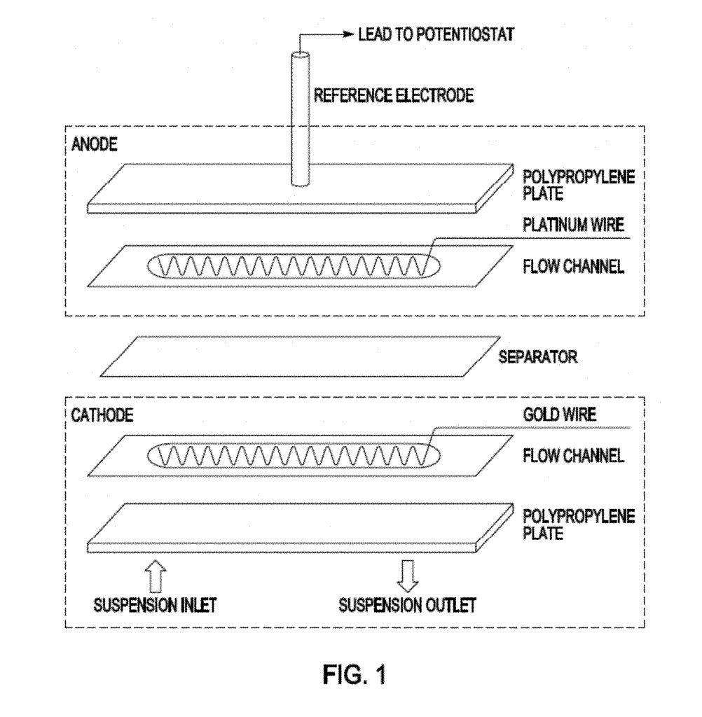

The electrochemical cell can include an anode, a cathode, a permeable membrane between the anode and cathode, and a fluid inlet and a fluid outlet. Fluid can flow into the electrochemical cell through fluid inlet and out of through the fluid outlet, FIG. 1. In various embodiments, the electrochemical cell can include a reference electrode. The reference electrode can be any suitable electrode used in electrochemistry applications, including H²/H+, Ag/AgCl, Ag/Ag₂SO₄, Hg/Hg₂Cl₂, Hg/Hg₂SO₄, Li/Li⁺, Na/Na⁺, and Hg/HgO. At least one of the anode or cathode can be a metal, such as a precious metal or a non-precious metal. Precious metals can include, without limitation, silver, platinum, gold, palladium, and combinations thereof. Non-precious metals can include, without limitation, lithium, aluminum, copper, nickel, titanium, aluminum, stainless steel, and combinations thereof. The anode or cathode can have any suitable shape not inconsistent with the methods described herein. Suitable shapes for the anode and cathode can include, without limitation, serpentine, straight line, mesh, flat plate, disc, cylinder, branched, and forest.

Perturbing the particles can also include stirring the dispersion including the particles in an electrochemical cell. Stirring of the dispersion in the electrochemical cell can be accomplished using any suitable means, such as using a stir bar and magnetic stir plate. The dispersion can be stirred at a rate of about 50 rpm to about 2500 rpm, about 50 rpm to about 2250 rpm, about 50 rpm to about 2000 rpm, about 50 rpm to about 1750 rpm, about 50 rpm to about 1500 rpm, about 50 rpm to about 1250 rpm, about 50 rpm to about 1000 rpm, about 50 rpm to about 750 rpm, about 50 rpm to about 500 rpm, about 50 rpm to about 250 rpm, about 100 rpm to about 2500 rpm, about 250 rpm to about 2500 rpm, about 500 rpm to about 2500 rpm, about 750 rpm to about 2500 rpm, or about 1000 rpm to about 2500 rpm. In various embodiments, the stir rate of the dispersion can be about 50 rpm, 100 rpm, 150 rpm, 200 rpm, 250 rpm, 300 rpm, 350 rpm, 400 rpm, 450 rpm, 500 rpm, 550 rpm, 600 rpm, 650 rpm, 700 rpm, 750 rpm, 800 rpm, 850 rpm, 900 rpm, 950 rpm, 1000 rpm, 1050 rpm, 1100 rpm, 1150 rpm, 1200 rpm, 1250 rpm, 1300 rpm, 1350 rpm, 1400 rpm, 1450 rpm, 1500 rpm, 1550 rpm, 1600 rpm, 1650 rpm, 1700 rpm, 1750 rpm, 1800 rpm, 1850 rpm, 1900 rpm, 1950 rpm, 2000 rpm, 2050 rpm, 2100 rpm, 2150 rpm, 2200 rpm, 2250 rpm, 2300 rpm, 2350 rpm, 2400 rpm, 2450 rpm, or 2500 rpm.

In various embodiments, the electrochemical cell includes an anode, a cathode, and a stir bar. In various embodiments, the electrochemical cell can include a reference electrode that can be any suitable reference electrode described herein. When the electrochemical cell is configured to include a stir bar, the dispersion can be stirred for 1 to 30 minutes at any specified stir rate described herein. After stirring for the specified time, the characteristics of the dispersion can be measured according to the methods described herein. In various embodiments, the dispersion is stirred while measuring the electrical response.

In various embodiments, the method further includes measuring at least two electrical responses to determine a resistance of the dispersion. Determining the resistance of dispersion can also include measuring at least three, four, five, six, seven, eight, nine, or ten electrical responses. The measuring of at least two electrical responses, in various embodiments, takes about 1 minute to about 120 minutes, 1 minute to about 100 minutes, 1 minute to about 90 minutes, 1 minute to about 80 minutes, 1 minute to about 70 minutes, 1 minute to about 60 minutes, 1 minute to about 50 minutes, 1 minute to about 40 minutes, 1 minute to about 30 minutes, 1 minute to about 20 minutes, 1 minute to about 10 minutes, 5 minutes to about 120 minutes, 10 minutes to about 120 minutes, 15 minutes to about 120 minutes, 20 minute to about 120 minutes, 25 minutes to about 120 minutes, 30 minutes to about 120 minutes, 40 minutes to about 120 minutes, 50 minutes to about 120 minutes, or 60 minute to about 120 minutes. In various embodiments, the measuring of at least two responses can take 1 minute, 2 minutes, 3 minutes, 4 minutes, 5, minutes, 6 minutes, 7 minutes, 8 minutes, 9 minutes, 10 minutes, 11 minutes, 12 minutes, 13 minutes, 14 minutes, 15 minutes, 20 minutes, 30 minutes, 40 minutes, 50 minutes, 60 minutes, 70 minutes, 80 minutes, 90 minutes, 100 minutes, 110 minutes, or 120 minutes.

In various embodiments, the liquid carrier includes an electrolyte. The electrolyte can be an aqueous electrolyte. Suitable aqueous electrolytes can include, without limitation, any water-soluble lithium or sodium salt, such as Li₂SO₄, LiNO₃, lithium oxalyldifluoroborate, LiBF₄, Li₃PO₄, LiClO₄, LiF, Na₂SO₄, NaNO₃, sodium oxalyldifluoroborate, NaBF₄, Na₃PO₄, NaClO₄, NaF, and combinations thereof. In various embodiments, the electrolyte is aqueous Li₂SO₄. The concentration of the aqueous lithium or sodium salt can be from about 0.01 M to about 5 M, about 0.1 M to about 5 M, about 0.5 M to about 4 M, about 0.5 M to about 3 M, or about 0.5 M to about 2 M. The concentration of the aqueous lithium or sodium salt can be about 0.01 M, 0.05 M, 0.1 M, 0.5 M, 1 M, 1.5 M, 2.0 M, 2.5 M, 3.0 M, 3.5 M, 4.0 M, 4.5 M, or 5.0 M.

In various embodiments, the electrolyte is an organic electrolyte. The organic electrolyte can include an organic solvent such as, without limitation, acetonitrile, N-methylpyrrolidine (NMP), dimethoxyethane (DME), dichloromethane, hexamethylphosphoramide (HMPA), dimethylformamide (DMF), tetrahydrofuran (THF), ethyl methyl carbonate, ethylene carbonate, propylene carbonate, and mixtures thereof. Other suitable organic solvents can include fluorinated and perfluorinated organic solvents, such as fluorinated lactones, fluorinated linear carboxylates, fluorinated cyclic carbonates, fluorinated linear carbonates, fluorinated monoethers, fluorinated diethers; boron-containing solvent such as borate esters and cyclic borate esters; phosphorus-containing solvents such as organic phosphates, phosphites, phosphonates, phosphazenes, and phosphonamidates; sulfur containing solvents such as ethyl methyl sulfone and sulfolane, and including solvents containing sulfide, sulfoxide, sulfone, sulfite, sulfonate, and sulfate, and mixtures of any of the foregoing organic solvents.

In various embodiments, the organic electrolyte includes at least one salt that is suitable for use as a salt in an organic electrolyte. The salt can be, for example, LiPF₆, LiBF₄, LiClO₄, fluoroorganic lithium salts such as (RSO₂)₃CLi, (RSO₂)₂NLi, and RSO₂OLi, where R is a fluorinated or perfluorinated C₁-C₅ alkyl, and mixtures thereof. Exemplary fluoroorganic lithium salts include lithium bis(trifluoromethansulfonyl)imide (LiTFSI). The concentration of the salt in the organic electrolyte can be from about 0.01 M to about 5 M, about 0.1 M to about 5 M, about 0.5 M to about 4 M, about 0.5 M to about 3 M, or about 0.5 M to about 2 M. The concentration of the salt in the organic electrolyte can be about 0.01 M, 0.05 M, 0.1 M, 0.5 M, 1 M, 1.5 M, 2.0 M, 2.5 M, 3.0 M, 3.5 M, 4.0 M, 4.5 M, or 5.0 M.

In various embodiments, the conductive particles include an alkali metal ion conducting material. The alkali metal ion conducting material can be a lithium-ion conducting material, a sodium-ion conducting material, and mixtures thereof. The lithium-ion conducting material can include LiFePO₄ (LFP), Li₄Ti₅Oi₂ (LTO), LiFeMnPO₄, LiCoO₂, LiMn₂O₄, LiNiMnCoO₂ (NMC), LiNiCoAlO₂, and mixtures thereof. In various embodiments, the lithium-ion conducting material is LFP or LTO. In various embodiments, the conductive particles themselves undergo an electrochemical reaction, where the particles become oxidized or reduced. The conductive particles, in various embodiments, do not cause oxidation or reduction in any of the components of the electrolyte in which they are dispersed.

In various embodiments, at least about 80% of the electrical resistance is due to the conductive particles. Without being bound by theory, the resistance measurements obtained with the methods described herein are due to collisions of particles with an electrode. In contrast, conventional methods typically have particles connected to the electrode statically through some form of processing for analysis/characterization. In various embodiments, at least about 80%, 81%, 82%, 83%, 84%, 85%, 86%, 87%, 88%, 89%, 90%, 91%, 92%, 94%, 94%, 95%, 96%, 97%, 98%, 99%, 99.5%, or 99.9% of the resistance is due to the conductive particles. The electrical resistance can be the resistance measured using the methods herein.

The conductive particles can have a charge or discharge capacity of about 0.01 mAh/g to about 400 mAh/g, about 0.1 mAh/g to about 350 mAh/g, about 0.1 mAh/g to about 300 mAh/g, about 0.1 mAh/g to about 250 mAh/g, about 0.1 mAh/g to about 200 mAh/g, about 0.1 mAh/g to about 150 mAh/g, about 0.1 mAh/g to about 100 mAh/g, about 0.1 mAh/g to about 50 mAh/g, about 1 mAh/g to about 350 mAh/g, about 5 mAh/g to about 350 mAh/g, about 10 mAh/g to about 350 mAh/g, about 25 mAh/g to about 350 mAh/g, about 50 mAh/g to about 350 mAh/g, about 100 mAh/g to about 300 mAh/g, about 110 mAh/g to about 250 mAh/g, or about 110 mAh/g to about 200 mAh/g. In various embodiments, the conductive particles can have a charge or discharge capacity of about 120 mAh/g to about 170 mAh/g. The conductive particles can have a charge or discharge capacity of about 0.01 mAh/g, 0.05 mAh/g, 0.1 mAh/g, 1 mAh/g, 5 mAh/g, 10 mAh/g, 25 mAh/g, 50 mAh/g, 75 mAh/g, 100 mAh/g, 110 mAh/g, 120 mAh/g, 130 mAh/g, 140 mAh/g, 150 mAh/g, 160 mAh/g, 170 mAh/g, 180 mAh/g, 190 mAh/g, 200 mAh/g, 220 mAh/g, 240 mAh/g, 260 mAh/g, 280 mAh/g, 300 mAh/g, 320 mAh/g, 340 mAh/g, 360 mAh/g, 380 mAh/g, or 400 mAh/g.

The dispersion can include about 0.001 vol % to about 20 vol % of the conductive particles. In various embodiments, the dispersion can include about 0.005 vol % to about 20 vol %, 0.01 vol % to about 20 vol %, 0.05 vol % to about 20 vol %, 0.1 vol % to about 20 vol %, 0.5 vol % to about 20 vol %, 1 vol % to about 20 vol %, 0.001 vol % to about 15 vol %, 0.001 vol % to about 10 vol %, 0.001 vol % to about 5 vol %, 0.1 vol % to about 10 vol %, or 0.5 vol % to about 5 vol %. The dispersion can include about 0.001 vol %, 0.05 vol %, 0.1 vol %, 0.5 vol %, 1 vol %, 1.5 vol %, 2 vol %, 2.5 vol %, 3 vol %, 3.5 vol %, 4 vol %, 4.5 vol %, 5 vol %, 5.5 vol %, 6 vol %, 6.5 vol %, 7 vol %, 7.5 vol %, 8 vol %, 8.5 vol %, 9 vol %, 9.5 vol %, 10 vol %, 12 vol %, 14 vol %, 16 vol %, 18 vol %, or 20 vol %. The vol % can be computed based on the volume and mass of electrolyte together with the mass of particles added. The density of the particles can be used to convert to volume, and a vol % can be obtained.

The conductive particles can have a BET surface area of about 0.01 m²/g to about 500 m²/g, about 0.01 m²/g to about 450 m²/g, about 0.01 m²/g to about 400 m²/g, about 0.01 m²/g to about 350 m²/g, about 0.01 m²/g to about 300 m²/g, about 0.01 m²/g to about 250 m²/g, about 0.01 m²/g to about 200 m²/g, about 0.01 m²/g to about 150 m²/g, about 0.01 m²/g to about 100 m²/g, about 0.01 m²/g to about 90 m²/g, about 0.01 m²/g to about 80 m²/g, about 0.01 m²/g to about 70 m²/g, about 0.01 m²/g to about 60 m²/g, about 0.01 m²/g to about 50 m²/g, about 0.01 m²/g to about 40 m²/g, about 0.01 m²/g to about 30 m²/g, about 0.01 m²/g to about 20 m²/g, about 0.05 m²/g to about 500 m²/g, about 0.1 m²/g to about 500 m²/g, about 0.5 m²/g to about 500 m²/g, about 1 m²/g to about 500 m²/g, about 5 m²/g to about 500 m²/g, about 10 m²/g to about 500 m²/g, about 25 m²/g to about 500 m²/g, about 50 m²/g to about 500 m²/g, about 75 m²/g to about 500 m²/g, about 100 m²/g to about 500 m²/g, about 150 m²/g to about 500 m²/g, about 200 m²/g to about 500 m²/g, about 300 m²/g to about 500 m²/g, or about 350 m²/g to about 500 m²/g. In various embodiments, the conductive particles can have a BET surface area of about 0.01 m²/g, 0.05 m²/g, 0.1 m²/g, 0.5 m²/g, 1 m²/g, 5 m²/g, 10 m²/g, 15 m²/g, 20 m²/g, 25 m²/g, 30 m²/g, 35 m²/g, 40 m²/g, 45 m²/g, 50 m²/g, 100 m²/g, 150 m²/g, 200 m²/g, 250 m²/g, 300 m²/g, 350 m²/g, 400 m²/g, 450 m²/g, or 500 m²/g. In various embodiments, the particles can have a BET surface area of about 0.5 m²/g to about 25 m²/g.

In various embodiments, the method further includes aging the dispersion for about 1 minute to about 30 days, about 1 minute to about 25 days, about 1 minute to about 20 days, about 1 minute to about 18 days, about 1 minute to about 16 days, about 1 minute to about 14 days, about 1 minute to about 12 days, about 1 minute to about 10 days about 1 minute to about 5 days, about 1 minute to about 2 days, about 5 minutes to about 30 days, about 15 minutes to about 30 days, about 30 minutes to about 30 days, about 60 minutes to about 30 days, about 120 minutes to about 30 days, about 240 minutes to about 30 days, or about 360 minutes to about 30 days to provide an aged dispersion; and detecting a change in the resistance of the aged dispersion compared to an identical dispersion that is not aged. Aging the dispersion can include preparing any of the dispersions described herein and letting the dispersion stand in a suitable container at room temperature (about 25° C.) for the specified time. Aged dispersion that settle during the aging process can be re-suspended to form a dispersion prior to the characterization of the dispersion. The dispersion can be aged for about 1 minute, 2 minutes, 3 minutes, 4 minutes, 5 minutes, 6 minutes, 7 minutes, 8 minutes, 9 minutes, 10 minutes, 30 minutes, 60 minutes, 120 minutes, 240 minutes, 360 minutes, 1 day, 2 days, 3 days, 4 days, 5, days, 6 days, 7 days, 8 days, 9 days, 10 days, 11 days, 12 days, 13 days, 14 days, 15 days, 16 days, 17 days, 18 days, 19 days, 20 days, 21 days, 22 days, 23 days, 24 days, 25 days, 26 days, 27 days, 28 days, 29 days, or 30 days.

In various embodiments, a method of characterizing a dispersion includes electrically applying an excitation signal to the dispersion; and measuring an electrical response elicited by the excitation signal. The dispersion includes electrically conductive particles of a lithium-ion conducting material and an aqueous electrolyte; and the particles are mechanically perturbed by flowing the dispersion including the particles through an electrochemical cell that includes a channel. In various embodiments, the lithium-ion conducting material is LFP or LTO. In various embodiments, the aqueous electrolyte is Li₂SO₄.

### System for Characterizing a Dispersion

In various embodiments, a system for characterizing a dispersion includes an anode, a cathode, an electrolyte; and a dispersion that includes electrically conductive particles and a liquid carrier. In various embodiments, the system includes any suitable reference electrode described herein.

At least one of the anode or cathode can be a metal, such as a precious metal or a non-precious metal. Precious metals can include, without limitation, silver, platinum, gold, palladium, and combinations thereof. Non-precious metals can include, without limitation, lithium, aluminum, copper, nickel, titanium, aluminum, stainless steel, and combinations thereof. The anode or cathode can have any suitable shape not inconsistent with the methods described herein. Suitable shapes for the anode and cathode can include, without limitation, serpentine, straight line, mesh, flat plate, disc, cylinder, branched, and forest. In various embodiments, at least one of the anode or the cathode has a serpentine shape. In various embodiments, the cathode includes aluminum. In various embodiments, the anode includes lithium. In various embodiments, the cathode includes gold. In various embodiments, the anode includes platinum.

In various embodiments, the liquid carrier includes an electrolyte. The electrolyte can be an aqueous electrolyte. Suitable aqueous electrolytes can include, without limitation, any water-soluble lithium or sodium salt, such as Li₂SO₄, LiNO₃, lithium oxalyldifluoroborate, LiBF₄, Li₃PO₄, LiClO₄, LiF, Na₂SO₄, NaNO₃, sodium oxalyldifluoroborate, NaBF₄, Na₃PO₄, NaClO₄, NaF, and combinations thereof. In various embodiments, the electrolyte is aqueous Li₂SO₄. The concentration of the aqueous lithium or sodium salt can be from about 0.01 M to about 5 M, about 0.1 M to about 5 M, about 0.5 M to about 4 M, about 0.5 M to about 3 M, or about 0.5 M to about 2 M. The concentration of the aqueous lithium or sodium salt can be about 0.01 M, 0.05 M, 0.1 M, 0.5 M, 1 M, 1.5 M, 2.0 M, 2.5 M, 3.0 M, 3.5 M, 4.0 M, 4.5 M, or 5.0 M.

In various embodiments, the electrolyte is an organic electrolyte. The organic electrolyte can include an organic solvent such as, without limitation, acetonitrile, N-methylpyrrolidine (NMP), dimethoxyethane (DME), dichloromethane, hexamethylphosphoramide (HMPA), dimethylformamide (DMF), tetrahydrofuran (THF), ethyl methyl carbonate, ethylene carbonate, and mixtures thereof. Other suitable organic solvents can include fluorinated and perfluorinated organic solvents, such as fluorinated lactones, fluorinated linear carboxylates, fluorinated cyclic carbonates, fluorinated linear carbonates, fluorinated monoethers, fluorinated diethers; boron-containing solvent such as borate esters and cyclic borate esters; phosphorus-containing solvents such as organic phosphates, phosphites, phosphonates, phosphazenes, and phosphonamidates; sulfur containing solvents such as ethyl methyl sulfone and sulfolane, and including solvents containing sulfide, sulfoxide, sulfone, sulfite, sulfonate, and sulfate, and mixtures of any of the foregoing organic solvents.

In various embodiments, the organic electrolyte includes at least one salt that is suitable for use as a salt in an organic electrolyte. The salt can be, for example, LiPF₆, LiBF₄, LiClO₄, fluoroorganic lithium salts such as (RSO₂)₃CLi, (RSO₂)₂NLi, and RSO₂OLi, where R is a fluorinated or perfluorinated C₁-C₅ alkyl, and mixtures thereof. Exemplary fluoroorganic lithium salts include lithium bis(trifluoromethansulfonyl)imide (LiTFSI). The concentration of the salt in the organic electrolyte can be from about 0.01 M to about 5 M, about 0.1 M to about 5 M, about 0.5 M to about 4 M, about 0.5 M to about 3 M, or about 0.5 M to about 2 M. The concentration of the salt in the organic electrolyte can be about 0.01 M, 0.05 M, 0.1 M, 0.5 M, 1 M, 1.5 M, 2.0 M, 2.5 M, 3.0 M, 3.5 M, 4.0 M, 4.5 M, or 5.0 M.

In various embodiments, at least about 80% of the electrical resistance is due to the conductive particles. Without being bound by theory, the resistance measurements obtained with the methods described herein are due to collisions of particles with an electrode. In contrast, conventional methods typically have particles connected to the electrode statically through some form of processing for analysis/characterization. In various embodiments, at least about 80%, 81%, 82%, 83%, 84%, 85%, 86%, 87%, 88%, 89%, 90%, 91%, 92%, 94%, 94%, 95%, 96%, 97%, 98%, 99%, 99.5%, or 99.9% of the resistance is due to the conductive particles. The electrical resistance can be the resistance measured using the methods herein.

In various embodiments, the conductive particles themselves undergo an electrochemical reaction, where the particles become oxidized or reduced. The conductive particles, in various embodiments, do not cause oxidation or reduction in any of the components of the electrolyte in which they are dispersed.

In various embodiments, the system further comprises a fluid inlet and a fluid outlet. In various embodiments, the dispersion including the conductive particles flows through the fluid inlet and fluid outlet. Fluid can flow into the electrochemical cell through the fluid inlet and out through the fluid outlet, FIG. 1. In various embodiments, the conductive particles are mechanically perturbed as they flow through the electrochemical cell, the fluid inlet, and the fluid outlet. Flowing of the dispersion can include the flow of the dispersion through one or more channels in an electrochemical cell, which can be effected by any suitable means for moving fluids. For example, a peristaltic pump can be used to move the dispersion through one or more channels, and/or through the fluid inlet and fluid outlet.

In various embodiments, the system further comprises a permeable separator between the anode and the cathode. In various embodiments, the permeable separator can prevent cross-mixing of the positive and negative electrolytes, but still allow the transport of ions to complete the circuit during the passage of current. The permeable separator can have high ionic conductivity, low water intake and be chemically and thermally stable. In various embodiments, the permeable separator is an anion exchange membrane or a cation exchange membrane. Cation exchange membranes contain negatively charged groups such as —SO₃⁻, —COO⁻, —PO₃²⁻, —PO₃H⁻, and/or —C₆H₄O⁻. Anion exchange membranes have positive functional groups such as —NH₃⁺, —NRH₂⁺, —NR₂H⁺, —NR₃⁺, and/or —SR₂⁺. In various embodiments, the permeable separator is a perfluorinated ion exchange membrane. The permeable separator can be about 5 μm to 100 μm thick. In various embodiments, the permeable separator can at least one polymer such as polypropylene, polyethylene, polybutylene, polyvinyl chloride, polystyrene, polyurethane, polysilane, and mixtures and co-polymers thereof. In various embodiments, the permeable separator can have at least one, at least two, at least three, at least four, or more layers of any of the materials described herein.

In various embodiments, the anode and the cathode are disposed between two non-conductive polymer surfaces (e.g., FIG. 1). In various embodiments, non-conductive polymer surfaces include at least one polymer such as polypropylene, polyethylene, polybutylene, polyvinyl chloride, polystyrene, polyurethane, polysilane, and mixtures and co-polymers thereof.

In various embodiments, the system can operate in batch mode in which the electrochemical characteristics of a series of materials have their DPR measured sequentially. After each material is measured, the electrochemical cell can be flushed out with an electrolyte solution, and a new material can be measured.

In various embodiments, a non-transitory computer-readable storage medium having computer-executable instructions stored thereon which, when executed by one or more processors, cause an apparatus to perform at least a portion of a technique for determining dispersed particle resistance (DPR) as described herein. The apparatus can include or can be coupled to an analytical instrument such as a chronoamperometer, a chronopotentiometer, or a combination thereof. The analytical device can measure the DPR of a sample of particles in a dispersion. The apparatus can provide a user interface that includes a plurality of user-editable fields for entering sample characteristics such as, for example, sample weight and/or sample density, and a user interface element that when triggered, sends a signal to the analytical device to measure the characteristics of the sample or to otherwise perform one or more techniques as shown and described elsewhere herein.

### EXAMPLES

Various embodiments of the present invention can be better understood by reference to the following Examples which are offered by way of illustration. The present invention is not limited to the Examples given herein.

### General Methods for LFP Materials

Six different LFP materials were characterized, referred to herein as LFP-1, LFP-2, LFP-3, LFP-4, LFP-5, and LFP-6. These materials were purchased from different suppliers and used as received. Scanning electron microscope (SEM) images were taken for all LFP materials with a Quanta 650 SEM to characterize the morphologies of the powders. A Panalytical X'pert diffractometer with Cu Kα radiation was used to obtain the X-ray diffraction (XRD) patterns of the materials between 20 values of 15 and 65 degrees. Tap densities were measured with a tap density analyzer with sample volumes of ˜6 mL in a 10-mL graduated cylinder (Quantachrome Instruments). Thermogravimetric analysis (TGA) of the LFP samples in air was conducted with a TA Instruments Q50. TGA was performed at a ramp rate of 5° C. min-1 from room temperature to 800° C. BET surface area of the LFP materials was determined with a surface area and pore size analyzer using nitrogen as the probe gas (NOVA 2200e). The Fe concentration of the electrolyte was measured using inductively coupled plasma optical emission spectroscopy (ICP) analysis (PerkinElmer Optima 8000). The typical concentration range for ICP analysis was 0.1 to 100 ppm for the element Fe. To prepare ICP samples, the electrolyte was carefully separated from the remaining solid LFP particles via filtration and then diluted to the desired concentration. The Fe concentration reported was the average of three separate measurements. The standard deviations of all ICP measurements were less than 1% of the reported average values.

### Example 1: Coin Cell Fabrication and Electrochemical Characterization

All LFP materials were characterized electrochemically first using conventionally fabricated coin cells. Electrochemical characterizations were carried out using CR2032-type coin cells with a LFP electrode as the working electrode and lithium foil as the counter and reference electrode, separated by a polypropylene/polyethylene/polypropylene trilayer membrane. LFP electrodes were prepared by first mixing 60 wt % LFP powder with 20 wt % carbon black and 20 wt % polyvinylidene difluoride (PVDF) binder, which was dissolved in N-methylpyrrolidone (NMP, Sigma-Aldrich®). Relatively high carbon content was used to ensure good connectivity and high conductivity between LFP particles and relatively high binder content was used to provide good mechanical robustness of the electrode films and adhesion to the current collector. For coin cells made to demonstrate the impact of excess carbon in the LFP samples, electrodes were also fabricated without any additional carbon black additive. These electrodes were comprised of 90 wt % LFP powder and 10 wt % PVDF binder. The mixtures were then pasted on an aluminum foil using a doctor blade with a gap thickness of 125 μm.

Electrodes were dried in an oven at 70° C. overnight and further dried in a vacuum oven at 70° C. for an additional three hours while applying vacuum. Electrode disks of 1.6 cm² were prepared using a punch, and the loading of LFP active material in the electrodes for all samples was ˜4 mg. The electrolyte for the coin cell measurements was 1.2 M lithium hexafluorophosphate (LiPF₆) in ethylene carbonate (EC) and ethyl methyl carbonate (EMC) with EC/EMC=3:7 volume ratio (BASF Corporation). The cells were assembled in an argon-filled glove box (with concentrations of both O₂ and H₂O<1 ppm) at room temperature. The galvanostatic charge-discharge cycling of coin cells were performed with a Maccor battery cycler. Where C rates are reported, they were determined by first measuring the gravimetric capacity of the LFP materials at 17 mA g⁻¹ LFP (measured capacities varied between 145 and 160 mAh g⁻¹ LFP). Then, the actual measured capacity at the low discharge rate was used for scaling C rates (e.g., for measured 160 mAh g⁻¹ LFP, 0.1 C was 16 mA g⁻¹ LFP, 1 C was 160 mA g⁻¹ LFP, and so on.). The cycling voltage window for LFP cells was 2.5 to 4.0 V (vs. Li/Li+).

### Example 2: Active Material Suspensions Electrochemical Evaluation

The aqueous electrolyte used for LFP suspensions was 1 M Li₂SO₄ (Fisher Scientific) dissolved in distilled water. LFP suspensions were prepared by dispersing LFP powders into the aqueous electrolyte agitated by a magnetic stir bar at 500 rpm for 5 minutes before electrochemical measurements, consistently for all measurements. Different loadings of LFP suspensions (0.2 vol %, 0.4 vol %, 0.7 vol %, 1.0 vol %, 1.5 vol %, 2.0 vol %, 3.0 vol %, and 4.0 vol %) were also prepared to characterize the effect of loading on the measured resistance. A customized cell was designed and assembled to electrochemically characterize the suspensions (FIG. 1). As shown in FIG. 1, channels for both cathode and anode were carved using a scalpel (Fisher Scientific) and separated by a porous polypropylene membrane (25 μm thick, Celgard®). Both channel dimensions were 10×0.5×0.2 cm³. The working electrode (cathode) was a gold wire (0.25 mm diameter and 30 cm length, Fisher Scientific). The counter electrode (anode) was a platinum wire (0.5 mm diameter and 8 cm length, Sigma Aldrich), and a Ag/AgCl electrode (Pine Instruments) was used as the reference electrode. Flow of the suspensions was provided by a MasterFlex peristatic pump (Cole-Parmer) at a rate of 82 mL min⁻¹. All electrochemical tests, including chronoamperometry and electrochemical impedance spectroscopy (EIS), on this custom device were performed with a Biologic SP-150.

### Example 3: Comparative Electrochemical Testing with Conventional Coin Cells

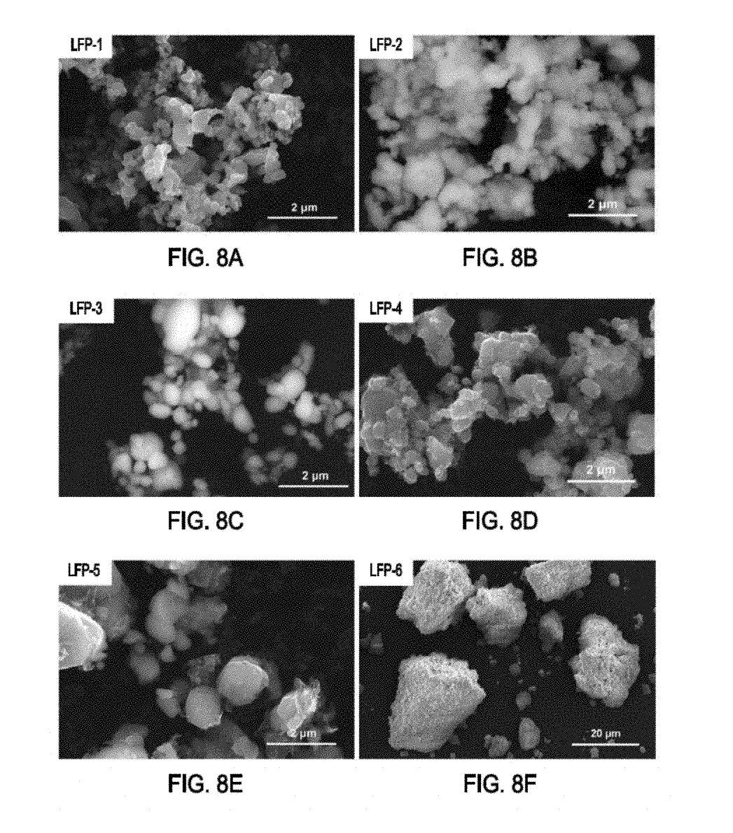

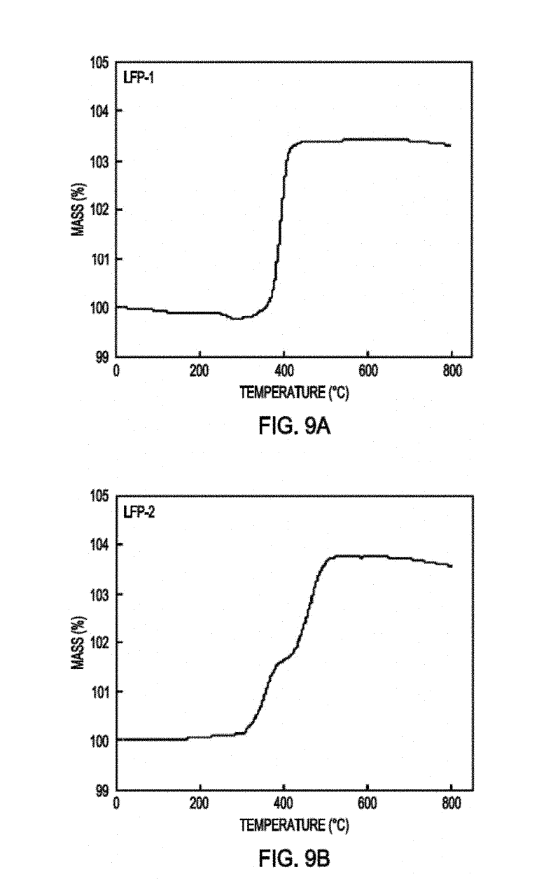

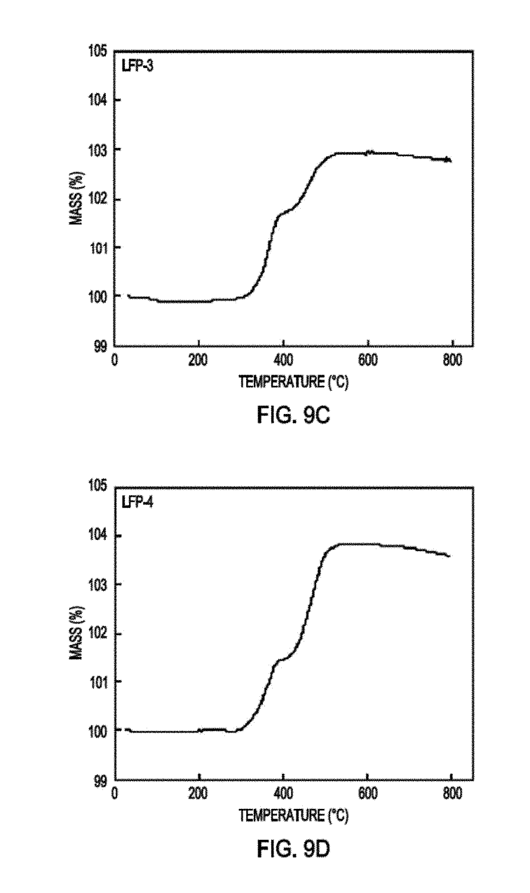

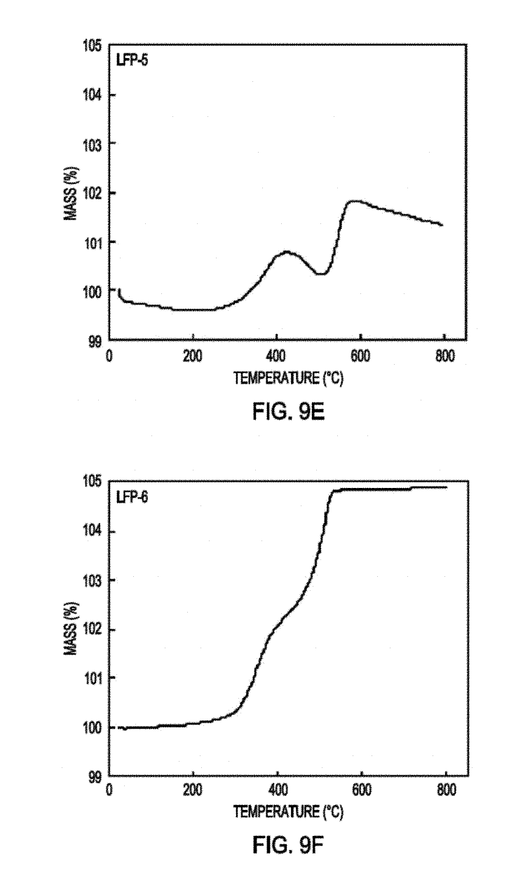

The LFP materials were characterized using XRD, SEM, TGA, BET, and tap density first to confirm their material properties. FIGS. 8A-8F show the scanning electron (SEM) images of LFP-1 to LFP-6, respectively. FIGS. 9A-9F show the thermogravimetric profiles for LFP-1 to LFP-6, respectively.

TABLE 1
Tap density, BET surface area, and lattice parameters of the LFP
materials. In Table 1, lattice parameters were calculated from
refinement of the Orthorhombic LFP peaks only. For tap density
and BET measurements, values reported represent the averages
and standard deviations for three independent measurements for
each material.

| | Tap Density | BET Surface Area | Lattice Parameter (Å) | | |
|---|---|---|---|---|---|
| Material | (g mL⁻¹) | (m² g⁻¹) | a | b | c |
| LFP-1 | 1.08 ± 0.01 | 7.5 ± 0.2 | 10.282 | 5.991 | 4.675 |
| LFP-2 | 1.07 ± 0.01 | 11.3 ± 0.1 | 10.296 | 5.994 | 4.677 |
| LFP-3 | 0.64 ± 0.01 | 14.9 ± 0.1 | 10.295 | 5.988 | 4.672 |
| LFP-4 | 1.15 ± 0.01 | 9.7 ± 0.2 | 10.247 | 5.977 | 4.669 |
| LFP-5 | 1.17 ± 0.01 | 17.5 ± 0.4 | 10.279 | 5.988 | 4.680 |
| LFP-6 | 1.04 ± 0.01 | 1.5 ± 0.3 | 10.280 | 5.988 | 4.671 |
| Aged LFP-3 | — | — | 10.296 | 5.994 | 4.677 |

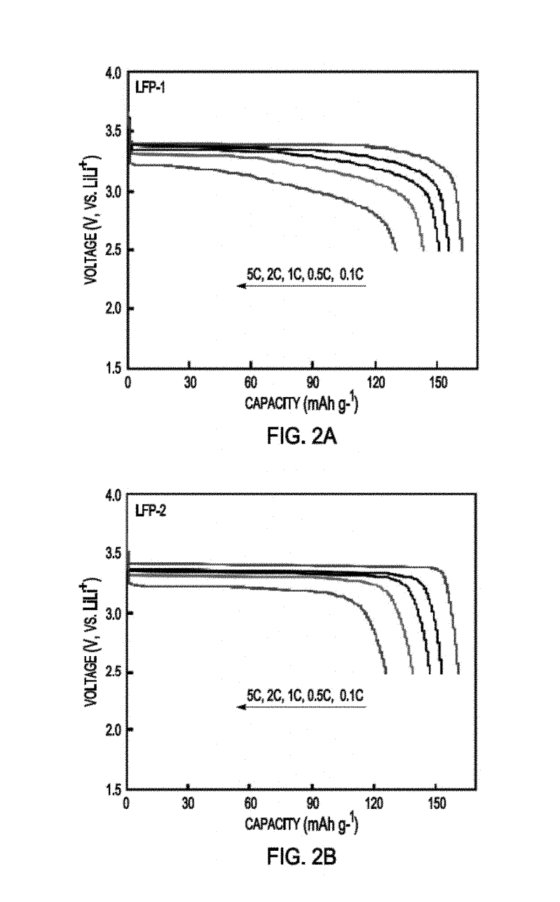

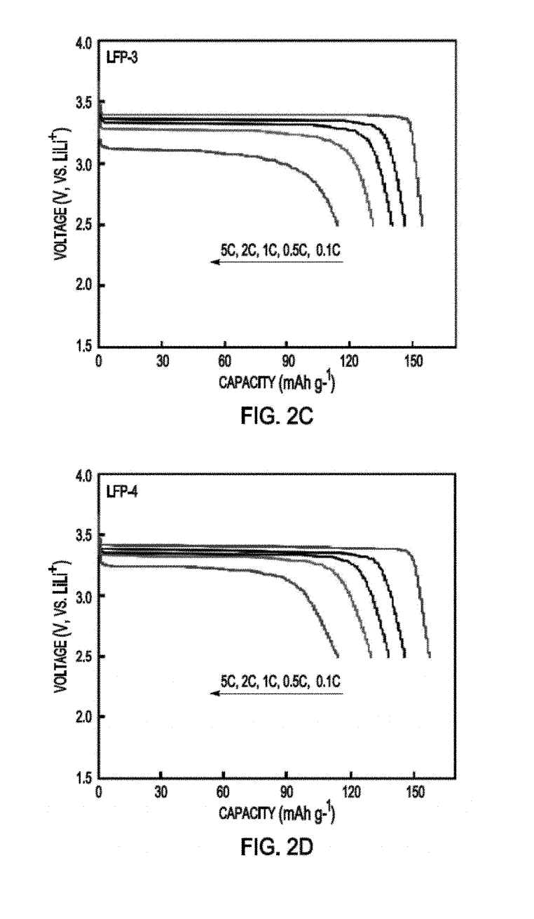

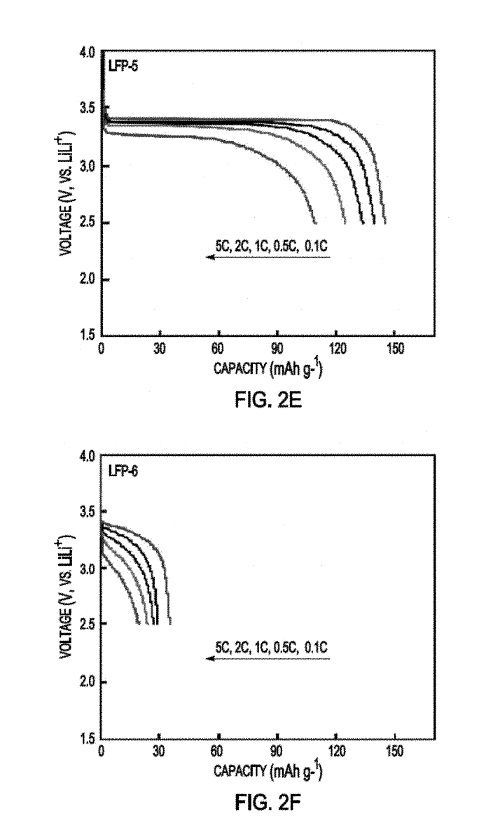

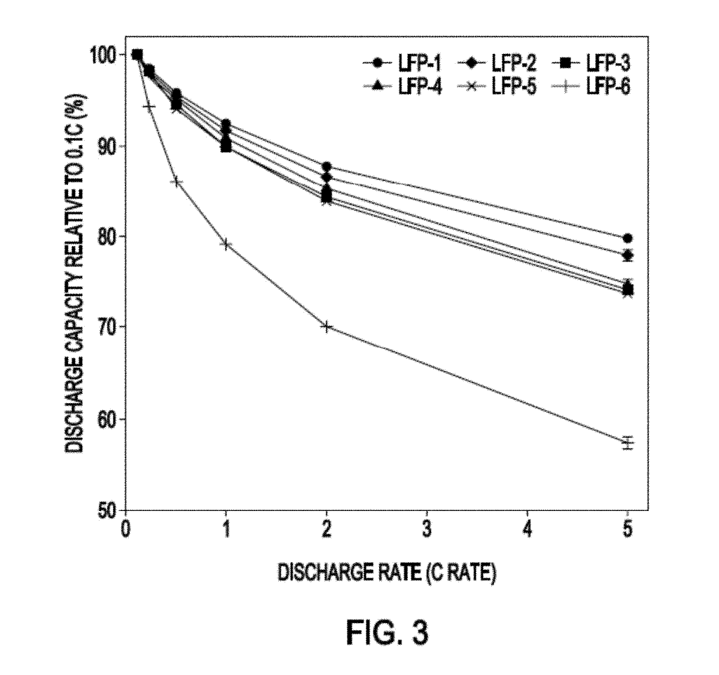

Conventional coin cells were then fabricated and cycled to evaluate electrochemical performance. The voltage profiles for the LFP materials at increasing rates of discharge (from 0.1 C to 10 C, all charge cycles were at 0.1 C) are shown in FIGS. 2A-2F. All LFPs had a flat discharge plateau at ˜3.45 V at low rates, which was consistent with other reports on LFP materials. Samples LFP-1 through LFP-5 had discharge capacities at low cycling rates that ranged from 145 to 160 mAh g⁻¹ LFP. These values were lower than the theoretical capacity of LFP (170 mAh g⁻¹ LFP), but within a similar range of other LFP material reports. LFP-6 showed a significantly lower capacity even at the low rate of 0.1 C, which can be attributed to the high impurity content which resulted in multiple impurity peaks in the XRD pattern of this material (FIG. 7). Discharge voltages and capacities for all six LFP materials decreased with increasing rate. This is typical and consistent with the literature due to increasing overpotential at increasing discharge current. However, the percentage of the capacity retention varied depending on the material. As shown in FIG. 3, LFP-1 showed the highest rate capability performance and LFP-6 the lowest. In FIG. 3, the LFP materials are designated as follows: circle: LFP-1; diamond: LFP-2; square: LFP-3; triangle: LFP-4; “x”: LFP-5; “+”: LFP-6, at different C-rates relative to the capacity at 0.1 C. Lines in FIG. 3 were added to guide the eye. Error bars in FIG. 3 represent the standard deviations of three measurements for each sample.

The capacity retention (in terms of the percentage of the discharge capacity relative to the capacity at 0.1 C) at increasing rates, or rate capability, generally followed the order of LFP-1>LFP-2>LFP-3>LFP-4>LFP-5>LFP-6. LFP-4 showed slightly higher capacity retention than LFP-3 at 5 C, although at this high current (˜2 mA cm⁻²) the lithium metal anode may begin to impact the measurements. These electrochemical measurements established the benchmark order of rate capability among the six LFP materials which were within identically processed composite electrodes.

### Example 4: Dispersion Particle Resistance (DPR) Characterization of LFP Dispersion

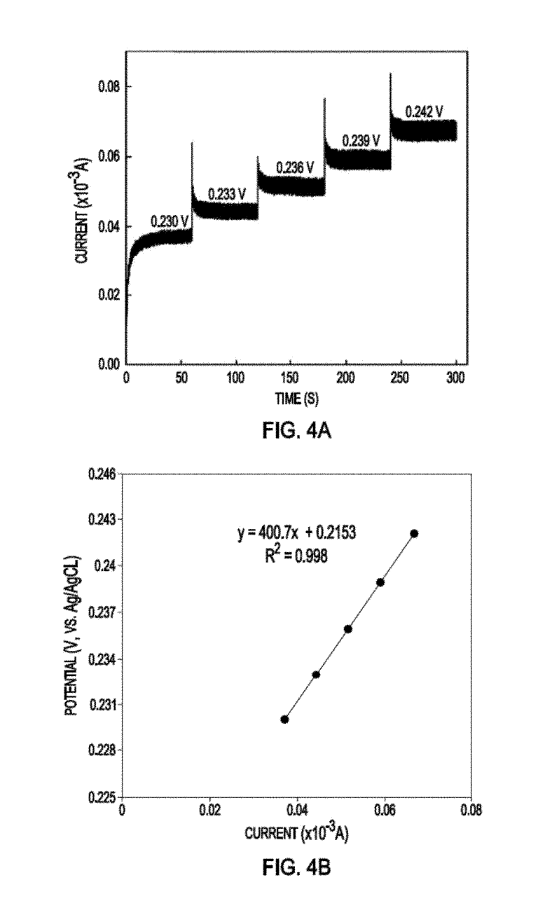

DPRs for LFP materials were measured using the following procedure. After dispersing a LFP powder in aqueous electrolyte, the suspension was electrochemically evaluated in a custom cell (shown in FIG. 1). A series of chronoamperometry tests at sequentially increasing potentials were performed for each suspension. Potentials were chosen such that the LFP particles were electrochemically oxidized/charged at each step. The potential and the average stabilized current for each step were retained for analysis. A plot of the potential vs. current resulted in a linear relationship for all electrochemical tests, and the slope of a linear fit of each data set was the DPR corresponding to a given material at a given loading (with loading referring to the vol % LFP in the electrolyte). An example of the linear potential vs. current data used to determine DPR, with 2 vol % LFP-3, is shown in FIGS. 4A-4B. A new plateau at an increased current resulted for each step increase of potential in FIG. 4A.

The average value of the current increased linearly with the increase in the applied potential. FIG. 4B shows the resulting data extracted from the experiment in FIG. 4A, with the applied potential vs. the average measured current of the last 10 seconds at that potential. For the example linear fit applied in FIG. 4B, the slope was 400.7 S (the DPR value) and R²=0.998, indicating a good fit. The measured DPR was the sum of all of the contributions to the electrode overpotential and was thus a combination of several resistances, including the resistance of the active material particles which were in contact with the current collector, ohmic resistance of the external electrical connections, and the ohmic resistance from the electrolyte. The combination of the latter two resistances ranged between 1.5-2.5Ω, as determined by the high frequency intercept of EIS measurements. The range of DPR values measured was between 38 and 1202Ω, indicating that the resistance arising from the LFP particles undergoing electrochemical oxidation was the primary contributor to the measured DPR and that the linear response of the DPR technique was not simply due to the electrolyte resistance.

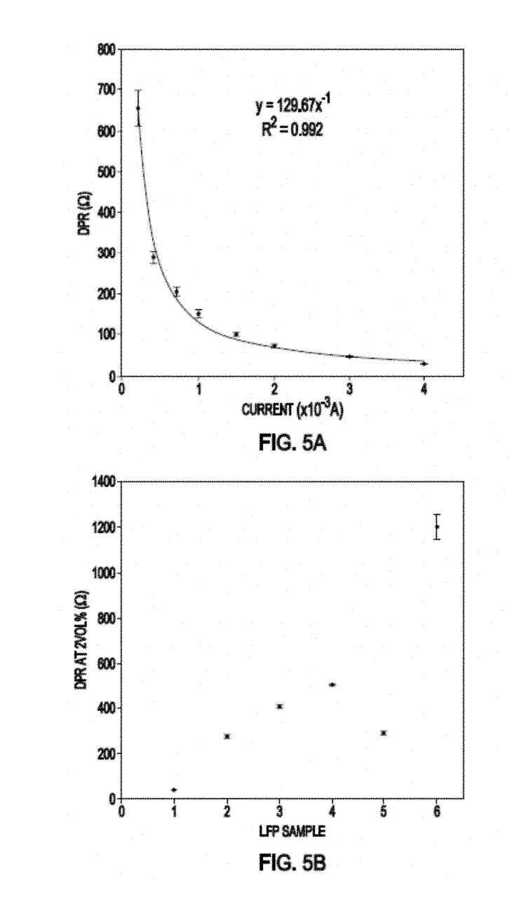

DPR values of a material can be influenced by a few key factors besides the intrinsic electrochemical properties of the active material, including, without limitation, the electrochemical cell design (cell size, wire length and geometry), suspension flow rate, and active material loading. The same cell was used for each series of measurements to exclude any cell variability, and the flow rate was also kept constant for all measurements. Material samples were evaluated in the flow cell in a sequential manner, with a rinsing step of passing LFP-free electrolyte through the cell preceding each new suspension measurement. To investigate the effect of active material loading in greater detail, LFP suspensions with different volumetric loadings were characterized in succession in a high throughput manner with the electrochemical flow cell (as an example LFP-1 is shown in FIG. 5A).

The DPR values decreased as LFP loadings increased for all LFP materials, and rate of decrease of DPR with increasing loading decreased as the loading increased. Both observations were consistent with electrochemical reactions of varying numbers of particles from the suspension on average in contact with the electrode. As active material loading increased, more particles were in contact with the current collector electrode on average at any given time and hence were participating in electrochemical reactions and the measured oxidation currents. The particles in contact with the electrode can each be considered as resistors connected in parallel. At higher volume fractions of LFP, there were more particles on the electrode surface, resulting in more resistors in parallel and hence decreased total resistance which decreased the measured DPR. Not only was the decrease in DPR with increased loading consistent with more resistors/particles in parallel, but the proportional relationship between LFP loading and resistance also supports this analysis. If resistance from a single particle in contact with the current collector was Rᵢ, then the collective resistance of N particle resistors in parallel (R_{N}) can be calculated with Equation 1:

$${R}_{N} = \frac{1}{{\sum }_{i = 1}^{N} \frac{1}{{R}_{i}}} \qquad ( Equation 1 )$$

Assuming the random sampling of the ensemble of particles in the dispersion to be relatively consistent, a representative resistance for each particle from a given LFP sample can be defined as R₀. This assumption should be reasonable because the number of particles was large even at low loadings and for a large batch of LFP sample there was not any particle sorting or separation to bias any particular dispersion. Using the assumption of a representative single resistance for each LFP sample, R_{N} would be R₀/N. Thus, the resistance due to the active materials, which dominates DPR measurements, may be expected to be inversely related with the number of active material particles in contact with the current collector and hence inversely related with the volumetric active material loading—at least at relatively low loadings of active material where the current collector surface was readily accessible. The inverse relationship between volumetric active material loading and DPR was supported by a least squares fit of the DPR measurements as collected at increasing loadings shown in FIG. 5A. DPR was inversely related with the LFP loading and the R² value of 0.992 indicates that the inverse relationship was a good fit of the collected data.

The inverse relationship between DPR and volumetric particle loading provided further evidence that DPR measured the collective resistance of the active material particles. The inverse relationship between volumetric loading and DPR was analogous to previously reported experiments of the relationship between active material loading and area specific impedance in coin cells. In both cases, the increase in particles participating in electrochemical reactions decreased the total cell resistance with an inverse relationship between particle loading and total measured resistance. Volumetric loading of 2 vol % LFP was chosen for further comparison between LFP materials because 1) the change in resistance above 2 vol % was relatively small, 2) higher loadings required more material and as an analytical technique smaller sample size was desirable, and 3) at very low loadings of LFP in some cases the variation in the measured resistance was relatively high, likely because at lower loadings the DPR measurement became more stochastic which resulted in more significant swings in the distribution of particles on the current collector relative to the mean distribution.

Lower DPR for a given material indicated that material should have a slower increase of overpotential at increasing current, and thus for appropriate materials processed into equivalent electrodes and battery cells, a material with a lower DPR could in general be expected to correlate to a higher voltage and better capacity retention at increasing currents. Thus, for a given set of materials those with lower DPR values could be expected to have better rate capability. DPR on LFP was a single measurement of multiple resistances, but was expected to be dominated by the ionic or electronic resistance of the active material particles. The total resistance in conventional electrodes is more complex and highly dependent on the fabrication process—though importantly DPR has the advantage of reducing the system complexity to identify what fraction of a cell resistance may be due to the active material. DPRs for all six LFP materials at 2 vol % were measured and the results are shown in FIG. 5B. The materials were numbered in order of decreasing rate capability where LFP-1 had the highest rate capability and LFP-6 had the lowest rate capability in identically processed and assembled coin cells. With the exception of LFP-5, the DPR showed an increasing trend from LFP-1 to LFP-6, with LFP-1 having the lowest DPR and LFP-6 having the highest DPR.

This DPR trend was generally consistent with expectations based on the relative rate capability order of these LFP materials, where the material with the lowest DPR had the highest rate capability and the material with the highest DPR had the lowest rate capability. The standard deviations were also very small relative to the measured DPR values, indicating good data consistency. DPR values were consistent for successive measurements of the same material over the measurement timescales of less than half an hour, and thus aging effects of the electrolyte (discussed in more detail herein) did not impact the relative DPR measurements in FIGS. 5A-5B. LFP-5 was the outlier in the DPR analysis with regards to the correlation to relative rate capability. Without being bound by theory, this deviation may be due to the higher carbon loading of 3.3 wt % (from TGA measurements, TGA results for all LFP materials can be found in FIGS. 9A-9F), compared to 0-2 wt % for the other LFP materials. This large amount of carbon additive likely decreased the DPR due to the formation of a conductive network within the suspension that effectively increased the number of particles in contact with the current collector via the carbon network and reduced the overall resistance.

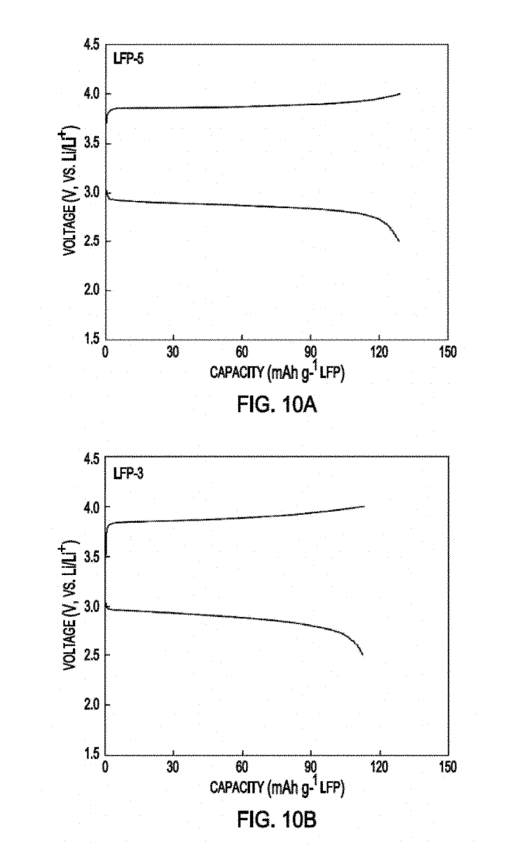

The relatively high 20 wt % carbon was originally chosen to minimize the contact and matrix resistance in the electrode such that the electrochemical performance was primarily limited by the resistance from the LFP active materials. To further demonstrate the impact of the high carbon in the LFP-5 material, coin cells were fabricated without any added carbon (composite electrode contained only active material and binder) and these electrodes were cycled in coin cells (for cycling profiles see FIGS. 10A-10C). FIGS. 10A-10C show the charge/discharge profile of the 4^{th} cycle of LFP-5, LFP-3, and LFP-4 electrodes fabricated without any additional conductive additive at 0.1 C (14.7 mA g⁻¹ LFP-5, 15.4 mA g⁻¹ LFP-3, 15.6 mA g⁻¹ LFP-4). Relative to electrodes with the same materials fabricated with conductive additives, LFP-5 obtained 87.5% of the discharge capacity, LFP-3 73.2%, and LFP-4 4.0%.

LFP-5 had better electrochemical performance than both LFP-3 and LFP-4 (two materials that had better rate capability than LFP-5 in electrodes with additional conductive additive, see FIGS. 2A-2F and 3) with regards to capacity at 0.1 C, further supporting the influence of excess carbon for LFP-5 impacting electrochemical analysis that does not have excess carbon to mitigate this effect. The results above demonstrate that DPR can provide relative rate capabilities for materials with similar physical properties. Outlier materials can also be identified when DPR analysis was combined with other techniques such as TGA.

### Example 5: DPR Sensitivity to LFP Aged in Electrolyte

As an example to demonstrate the sensitivity of the DPR technique, measurements were made on the same LFP material both pristine and after aging in the electrolyte. LFP has previously been reported to have reduced electrochemical performance after being aged in water or aqueous electrolyte. After aging, measured impacts to LFP include increased electrode polarization, decreased capacity, dissolution of chemical species, and in some cases a change in the crystalline phases observed in the material. These performance decays can even occur during storage in humid environments, thus the storage history of LFP materials can be very important. LFP changes due to contact with water in many cases proceeded slowly, and detecting these changes can be challenging without fabricating electrodes with the LFP material and performing electrochemical evaluation. As mentioned herein, this procedure can be very time consuming. The method described herein, in various embodiments, allows for the fast detection of the electrochemical performance decay of LFP.

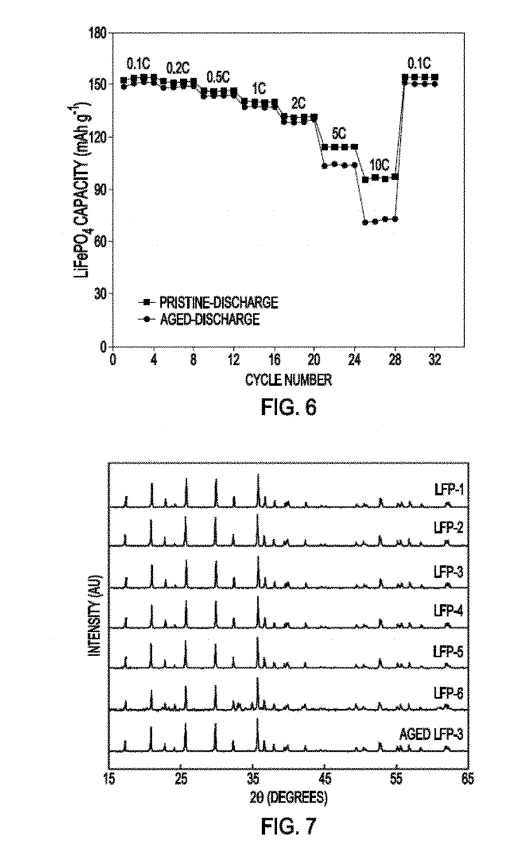

As an initial demonstration of the concept of detecting LFP aging using DPR, LFP-3 was mixed with 1 M Li₂SO₄ electrolyte and aged for 15 days. After aging, the LFP was rinsed, dried, and then fabricated into electrodes and evaluated in conventional coin cells via identical procedures for the LFP batteries described earlier. A representative example of LFP-3 coin cell discharge capacity at different cycling rates, using LFP-3 material both before and after aging in electrolyte for 15 days is shown in FIG. 6. ICP measurements on the electrolyte confirmed that ˜0.2% of the Fe present in the LFP had dissolved after 15 days (with total Fe concentration in the electrolyte 1 mM). While the discharge capacity at low discharge rates only dropped ˜1% after aging, the high rate capacity retention dropped significantly. Relative to unaged LFP-3, the aged LFP-3 was only able to achieve ˜93% of the capacity at 5 C and ˜80% of the capacity at 10 C.

This performance impact was consistent with other reports on aged LFP materials in aqueous electrolyte or water. DPR tests were also conducted for both unaged and aged LFP-3 at a loading of 2 vol %. The aged LFP had a 30% increase of DPR from the unaged material (from 467.8Ω to 626.1Ω). This 10-minute DPR measurement detected a significant change in the aged material, indicating that DPR has the sensitivity to detect aging effects in LFP that can dramatically impact rate capability. Aged LFP did not have any significant changes in the XRD pattern relative to the pristine material (FIG. 7) and advantageously the DPR analysis required a timescale three orders of magnitude less than the coin cell validation of the aging impact on rate capability.

The DPR measurements described above were able to identify variations in relative rate capability between different materials and changes to the rate capability of a material due to aging. These rate capability changes, and corresponding DPR resistances, reflect the resistance of the active material particles during electrochemical oxidation. The total resistance due to the LFP active material can be dependent on the ionic and/or electronic conductivity of the particles, the size of the particles, and the number of particles contributing to the electrochemical reactions. Thus, if the particle size distribution of the LFP particles is determined from another technique, DPR can be used to determine the initial conductivity of LFP particles.

### General Methods for LTO Materials

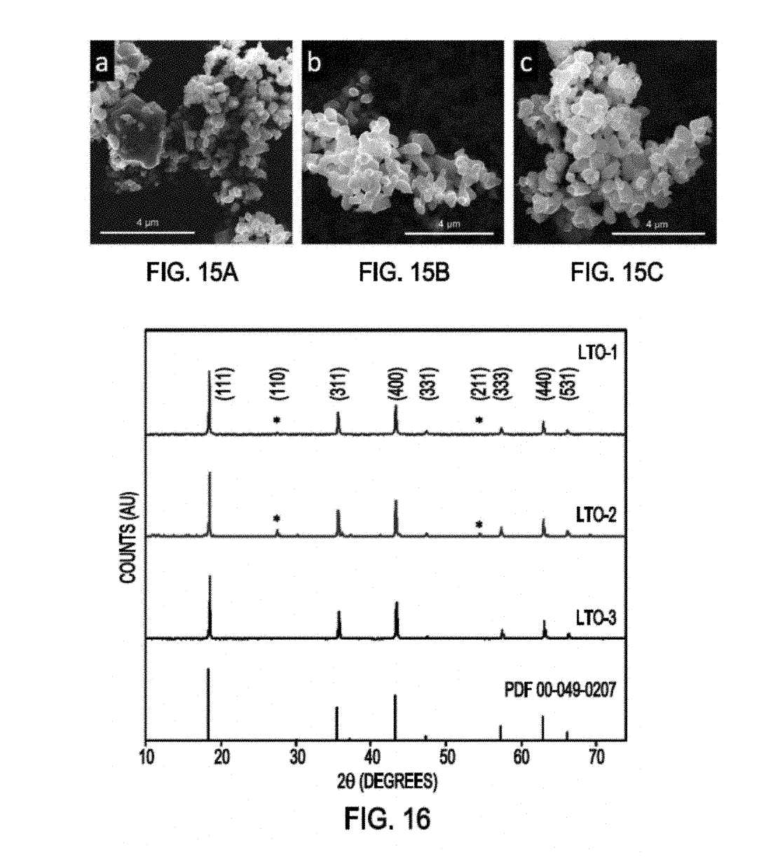

Another lithium-ion battery active material used to demonstrate the method in this report was the anode material Li₄Ti₅O₁₂ (LTO). LTO was chosen because it is a well characterized lithium-ion battery anode material with high rate capability, and the rate capability has previously been demonstrated to vary significantly across LTO material produced using different methods. The flat discharge potential of LTO is beneficial for measuring a stable potential when using constant current testing. Three LTO materials from either different suppliers or synthesized in lab were first characterized in conventional coin cells using existing methods to measure the capacity retention at increased rates of discharge and the mass electrode resistance. Three LTO materials were used in this study, which we refer to as LTO-1, LTO-2, and LTO-3. LTO-1 and LTO-3 were obtained from battery material vendors. LTO-2 material was synthesized following a solid state calcination method previously published in the literature. A mixture of anatase titanium oxide (Acros Organics) and lithium hydroxide (Fisher Scientific, 4% excess than stoichiometric amount) was calcined in a Carbolite CWF 1300 box furnace in an air atmosphere by heating at an incremental rate of 3° C. min⁻¹ up to 800° C. and then holding at this temperature for 20 hours before turning off the furnace and allowing cooling down to ambient temperature without control over the cooling rate. To characterize the morphologies of the materials, scanning electron microscope (SEM) images were taken for all three LTO materials with a Quanta 650 SEM (FIGS. 15A-15C). A Panalytical X'pert diffractometer with Cu Kα radiation was used to obtain the X-ray diffraction (XRD) patterns of the materials (FIG. 16). Tap densities were measured with a tap density analyzer (Quantachrome Instruments).

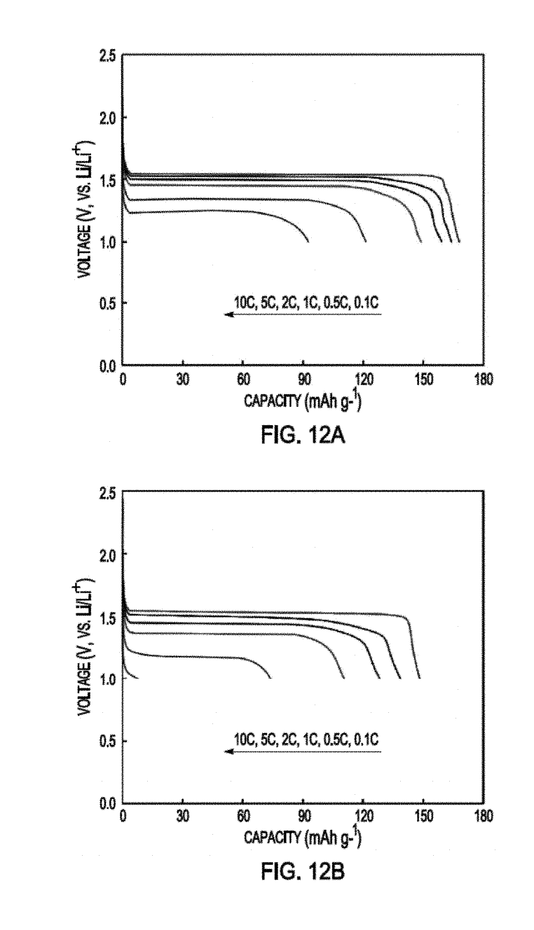

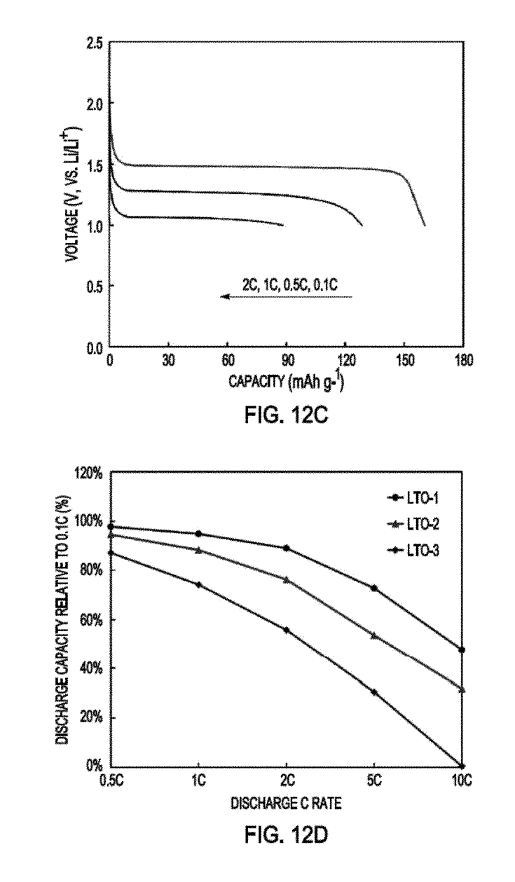

TABLE 2
Standard deviations of three coin cells of each LTO material
of the discharge capacity relative to 0.1 C at increasing C
for the data shown in FIG. 12D.

| | C Rate | | | | |
|---|---|---|---|---|---|
| Material | 0.5 C | 1 C | 2 C | 5 C | 10 C |
| LTO-1 | 0.09% | 0.08% | 0.07% | 0.70% | 4.23% |
| LTO-2 | 0.06% | 0.10% | 0.15% | 0.28% | 1.40% |
| LTO-3 | 0.60% | 0.28% | 0.15% | 1.04% | 0.24% |

### Example 6: Coin Cell Fabrication and Electrochemical Characterization

Electrochemical characterizations were carried out using CR2032-type coin cells with LTO electrode as the working electrode and lithium foil as the counter and reference electrode, separated by a polypropylene/polyethylene/polypropylene trilayer membrane. LTO electrodes were prepared by first mixing 80 wt % LTO powder with 10 wt % carbon and 10 wt % polyvinylidene difluoride (PVDF) binder, which was dissolved in N-methylpyrrolidone (NMP, Sigma-Aldrich®). The mixtures were pasted on aluminum foil using a doctor blade. Electrodes were then dried in the oven at 70° C. overnight followed by further drying in a vacuum oven at 70° C. for three hours. Electrode disks of 1.6 cm² were prepared using a punch, and the loading of LTO active material in the electrodes for all samples was ˜10 mg. The electrolyte used was 1.2 M lithium hexafluorophosphate (LiPF₆) in ethylene carbonate (EC) and ethyl methyl carbonate (EMC) with EC/EMC=3:7 by volume ratio (BASF Corporation). The cells were assembled in an argon-filled glove box (with concentrations of both O₂ and H₂O<1 ppm) at room temperature. The galvanostatic charge-discharge tests of coin cells were performed with a Maccor battery cycler. For experimental results where the C rate is given, 1 C was assumed to be 175 mA g⁻¹ LTO active material, with the rate scaled by the amount of active material loaded into each individual electrode. The cycling window for LTO cells was 1.0 to 2.5 V (vs. Li/Li+).

### Example 7: Active Material Suspensions Electrochemical Evaluation

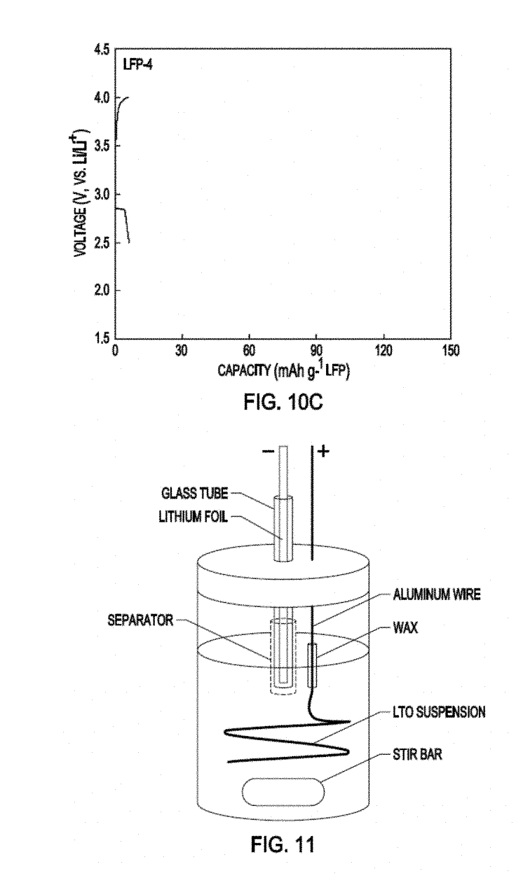

LTO suspensions were prepared by dispersing the LTO powder in the electrolyte (using agitation provided by a magnetic stir bar at 400 rpm). Three different loadings of LTO suspensions (0.5 vol %, 1 vol % and 2 vol %) were prepared for each LTO material. Loadings were kept low to minimize the formation of larger particle flocculates. A customized cell was designed and assembled to characterize the suspensions. As shown in FIG. 11, the cathode current collector was an aluminum wire (9.4 cm² total surface area immersed in the suspension, Fisher Scientific) surrounded by the LTO suspension, which was agitated by a stir bar. The active surface area of the aluminum wire was controlled by coating wax at the liquid-gas interface, creating an inert surface on the wire even if the interface underwent fluctuations due to the agitation of the suspension. The anode (and reference electrode) was a piece of lithium foil. The cathode and anode were separated by a glass tube and a polypropylene/polyethylene/polypropylene trilayer membrane. The cell was assembled and tested in the argon-filled glove box. All electrochemical tests on this customized device were performed with a Biologic SP-150.

### Example 8: Electrochemical Testing on Conventional Cells

The LTO materials were electrochemically tested in conventional coin cells to determine the rate capability for benchmarking. Both the discharge profiles and the discharge capacities at increasing rates of discharge (cells were cycled between 0.1 C and 10 C) are shown in FIGS. 12A-12D. In FIG. 12D, the LTO materials are represented as follows: circles: LTO-1; triangles: LTO-2; and diamonds: LTO-3. All three LTO electrodes had flat discharge curves at ˜1.5 V at low cycling rates, which is consistent with other reports on LTO materials in the literature. Discharge capacities for all three LTO materials decreased with increasing rates, which is typical because of increasing overpotential at increasing discharge currents. At each C-rate, the capacity retention (in terms of the percentage of the discharge capacity relative to the capacity at 0.1 C) follows the ranking order of LTO-1>LTO-2>LTO-3. This difference became more pronounced as the rate of discharge was increased. LTO-3 lost almost all discharge capacity when cycled at 10 C. However, LTO-1 still maintained ˜50% of the capacity at this rate. This test was highly reproducible and the standard deviation of capacity retention for three coin cells of each LTO material was below 1% for most rates tested (see Table 2 for standard deviation of capacity retentions at different C rates). While the low-rate capacities (0.1 C) for LTO-1 and LTO-3 were very close (˜165 mAh g⁻¹), LTO-2 had a significantly lower capacity (˜148 mAh g⁻¹) that can be attributed to significant rutile TiO₂ impurity phase in this material. This electrochemical testing was primarily done to establish the baseline order of rate capability between the materials with LTO-1 having the highest rate capability and LTO-3 having the lowest rate capability.

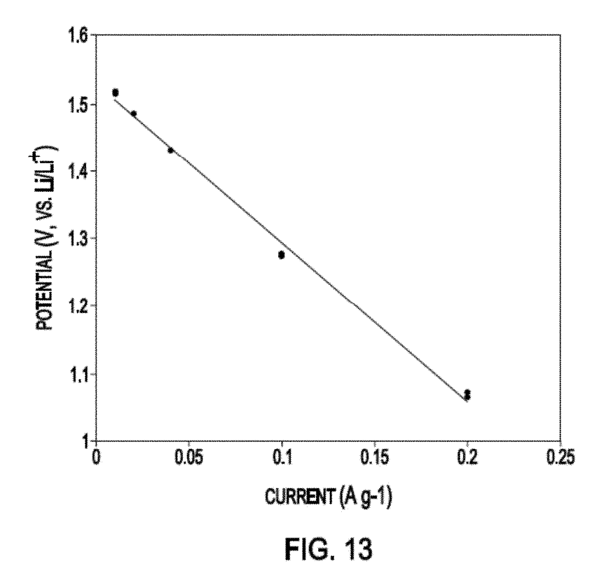

Using the discharge profiles at various discharge currents in FIGS. 12A-12C, the potential at 25 mAh g⁻¹ (the same state of charge) was extracted to determine the mass electrode resistance (or Rₘ, units of Ω-g) using methods previously reported in the literature. The potential as a function of the current (divided by the mass of active materials) displayed a linear relationship, with a representative example shown for LTO-3 in FIG. 13. We note that for each current in FIG. 13 there are four separate data points representing the potential measured for four successive discharge cycles under the same conditions, but that the high reproducibility of the measured potentials results in difficulty in distinguishing the four individual data points in the figure. A linear fit of data such as that displayed in FIG. 13 provides a slope which is the parameter previously referred to as the Rₘ. We measured the Rₘ values for LTO-1, 2, and 3 to be 0.693, 0.847, and 2.357Ω-g, respectively. Increasing values of Rₘ correlated with decreasing rate capability of the LTO materials, consistent with previous reports on other lithium-ion battery electrode materials. Rₘ is particularly useful in comparing between materials because it normalizes the effects of material loading on the resistance of the electrode and rate capability. Rₘ provides a single straightforward parameter that can be used to compare the discharging resistance among different active electrode materials, and because lower resistance results in lower overpotential lower Rₘ materials have higher rate capabilities as long as everything else regarding the cells has been held equivalent.

Although Rₘ is a valuable parameter to use that correlates to the rate capability of active materials, it still requires electrode and cell fabrication and many charge/discharge cycles at different rates which take significant time. Also, while Rₘ in many cases is dominated by the resistance of the active material itself, it is also influenced by other factors in the electrode, such as the particle “wiring.” Also, the influence of active material loading is compensated by the mass term in Rₘ only within a particular range of loading. The electrode microstructure still influences the Rₘ value measured, and thus a method to interrogate the active material without electrode microstructure effects would be desirable. A technique that does not involve electrode fabrication to electrochemically probe the active materials could in principle remove the contributions from electrode microstructure and non-active material components.

### Example 9: LTO Suspension Testing and Rate Capability Correlation

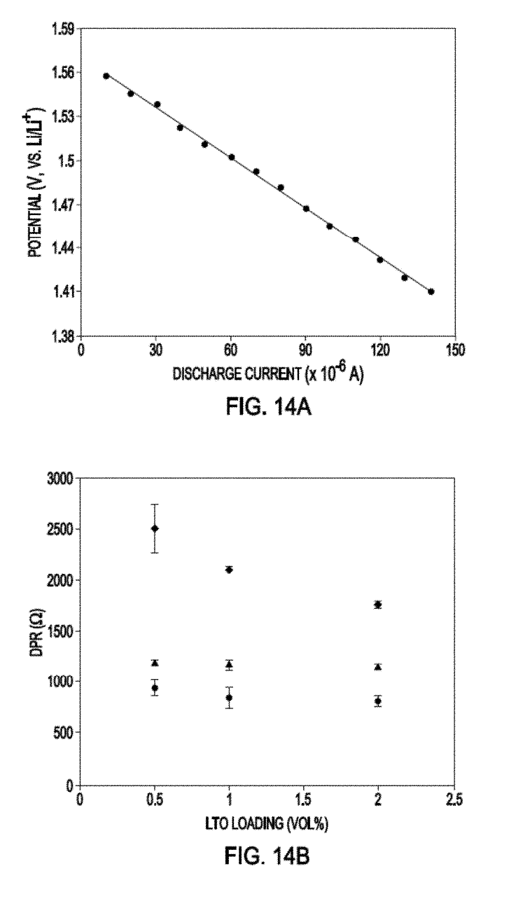

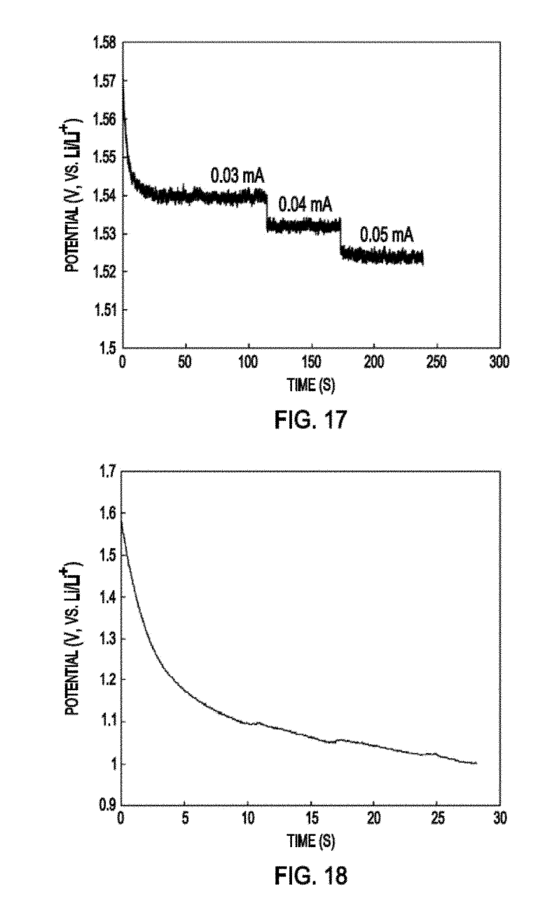

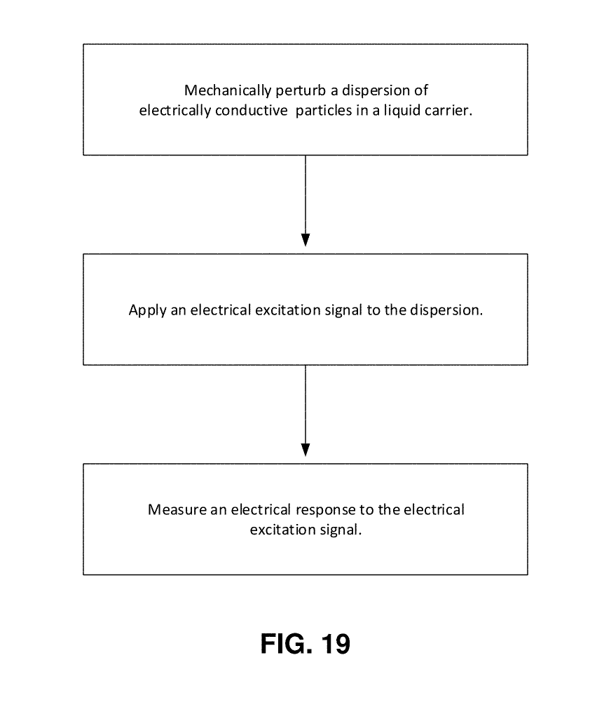

A customized electrochemical cell was designed (shown in FIG. 11) to characterize LTO active material suspensions. After dispersing the powder in the electrolyte, a series of chronopotentiometry (CP) tests at systematically increasing discharge currents were performed. An example of a sequence of CP tests can be found in FIG. 17, though this example has relatively few current steps compared to most of the measurements discussed below. The potential quickly stabilized after an initial drop in potential due to the capacitance of the electric double layer. After reaching a stable plateau, the average potential of the final 20 seconds at a given current was determined. These average potentials have a linear decrease as the discharge current is increased (see FIG. 14A as an example for LTO-2 with 2 vol % loading). Data such as that found in FIG. 14A was used for a linear fit (dashed line, R²=0.999) and the slope was extracted from this fit. The slope is the dispersed particle resistance (DPR), which has units of Ω. DPR measures the increasing rate of overpotential over increasing current for the particles contacting the electrode in the dispersions. A higher DPR means a faster increase of overpotential while increasing the discharge current, which we hypothesized would indicate a material has a lower rate capability. Importantly, this technique provides a significant measured current from only the active material particles when the particles are actively colliding with the current collector (FIG. 18).

Thus, the DPR technique can probe a resistance that is the sum of many resistances in the system, including the resistance of the active material particles, Ohmic resistance from the circuit, and resistance from the electrolyte. The combined value of these later two resistances was consistently found to be between 125Ω and 140Ω from the high frequency intercept of electrochemical impedance spectroscopy measurements, which was always less than 20% of DPR and can be subtracted from the measured resistance for normalizing between measurements. Thus, DPR can be sensitive to the active material particles and the variability due to electrolyte/cell resistance is low. The primary contribution to DPR is from the active material particles, which consists of resistance due to the particle electronic and ionic conductivity as well as activation resistance. Each of these factors can be challenging to measure individually and vary across multiple orders of magnitude with different methods. The DPR approach provides a collective measure that indicates the overall average resistance from an ensemble of the active material particles.

To confirm the relative correlation between DPR and rate capability, DPR measurements were performed on all three LTO materials at 0.5, 1, and 2 vol % LTO loading in electrolyte and the results are shown in FIG. 14B. The DPR across all suspension loadings went in the order of LTO-3>LTO-2>LTO-1. Notably, this is the same order as the Rₘ measurements and has the same general trend that a greater DPR value correlates with a lower rate capability of the active material. FIG. 14B also shows that DPR decreased as the loading increased for each material. This increase of active material loading results in an increase in the particles in contact with the current collector on average, which increases the effective active material surface area and hence decreases the resistance. A similar effect has been shown previously for conventional coin cells in the literature. In the DPR system, a higher active material loading in the suspension increases the areal density of particles in the fluid contacting the current collector, which should result in more total active material particles in contact with the current collector and contributing to the electrochemical reactions at any given time.

Thus, the total electroactive material area in contact with the current collector is increased, similar to increasing the active material loading or thickness in a conventional coin cell as was the case in the studies mentioned above that measured and predicted decreased resistance under such conditions. These results demonstrated the sensitivity of the DPR technique both to the properties and the amount of electroactive material within the suspension. The DPR measurements and the previous literature discussed above lead us to expect that the measured DPR will decrease with increased active material loading in the electrolyte, decrease with an increase in the ionic and electronic conductivities of the active material, and increase with an increase in particle size.

A major benefit of the DPR method is that the measurement can be made in a convenient way without electrode fabrication, and thus is relatively fast and does not have contributions from other electrode components or the electrode microstructure and connectivity. Additionally, because the suspension is agitated and there are many different particles that are coming into contact with the electrolyte, the measured resistance is an average of contributions from the ensemble of particles in the powder. Thus the technique is representative of the polydisperse particle population of interest, as opposed to single particles selected from within that population. While more materials need to be tested to more generally affirm the DPR technique limits and reliability, these three materials show that a quick DPR measurement provides insights into the relative rate capabilities of the active materials. Most of the DPR measurements took less than 30 minutes total in sample preparation and CP testing.

The terms and expressions that have been employed are used as terms of description and not of limitation, and there is no intention in the use of such terms and expressions of excluding any equivalents of the features shown and described or portions thereof, but it is recognized that various modifications are possible within the scope of the embodiments of the present invention. Thus, it should be understood that although the present invention has been specifically disclosed by specific embodiments and optional features, modification and variation of the concepts herein disclosed may be resorted to by those of ordinary skill in the art, and that such modifications and variations are considered to be within the scope of embodiments of the present invention.

### Enumerated Embodiments

The following exemplary embodiments are provided, the numbering of which is not to be construed as designating levels of importance:

Embodiment 1 provides a method of characterizing a dispersion, comprising electrically applying an excitation signal to the dispersion; and measuring an electrical response elicited by the excitation signal; wherein the dispersion comprises electrically conductive particles and a liquid carrier; and wherein the particles are mechanically perturbed.

Embodiment 2 provides the method of embodiment 1, wherein the excitation comprises a specified voltage or series of voltages applied to the dispersion and wherein the electrical response comprises a measured current.

Embodiment 3 provides the method of any one of embodiments 1-2, wherein the excitation comprises a specified current or series of currents applied to the dispersion and wherein the electrical response comprises a measured voltage.

Embodiment 4 provides the method of any one of embodiments 1-3, wherein perturbing the particles comprises agitating the particles in a vessel.

Embodiment 5 provides the method of any one of embodiments 1-4, wherein perturbing the particles comprises flowing the dispersion including the particles through an electrochemical cell comprising a channel.

Embodiment 6 provides the method of any one of embodiments 1-5, wherein the electrochemical cell comprises: an anode; a cathode; a permeable membrane between the anode and cathode; and a fluid inlet and a fluid outlet.

Embodiment 7 provides the method of any one of embodiments 1-6, wherein at least one of the anode or cathode comprises a precious metal or a nonprecious metal.

Embodiment 8 provides the method of any one of embodiments 1-7, wherein at least one of the anode or the cathode has a serpentine shape.

Embodiment 9 provides the method of any one of embodiments 1-8, wherein perturbing the particles comprises stirring the dispersion including the particles in an electrochemical cell.

Embodiment 10 provides the method of any one of embodiments 1-9, wherein the electrochemical cell comprises an anode; a cathode; and a stir bar.

Embodiment 11 provides the method of any one of embodiments 1-10, further comprising measuring at least two electrical responses to determine a resistance of the dispersion.

Embodiment 12 provides the method of any one of embodiments 1-11, wherein the measuring at least two electrical responses takes about 1 to 120 minutes.

Embodiment 13 provides the method of any one of embodiments 1-12, wherein the liquid carrier comprises an electrolyte.

Embodiment 14 provides the method of any one of embodiments 1-13, wherein the electrolyte is an aqueous electrolyte.

Embodiment 15 provides the method of any one of embodiments 1-14, wherein the electrolyte is aqueous Li₂SO₄.

Embodiment 16 provides the method of any one of embodiments 1-15, wherein the conductive particles comprise an alkali metal ion conducting material.

Embodiment 17 provides the method of any one of embodiments 1-16, wherein the alkali metal ion conducting material is a lithium-ion conducting material, a sodium-ion conducting material, or mixtures thereof.

Embodiment 18 provides the method of any one of embodiments 1-17, wherein the lithium-ion conducting material LiFePO₄ (LFP), Li₄Ti₅O₁₂ (LTO), LiFeMnPO₄, LiCoO₂, LiMn₂O₄, LiNiMnCoO₂ (NMC), LiNiCoAlO₂, or mixtures thereof.

Embodiment 19 provides the method of any one of embodiments 1-18, wherein the lithium-ion conducting material is LFP or LTO.

Embodiment 20 provides the method of any one of embodiments 1-19, wherein at least 80% of the electrical resistance in the electrochemical cell is due to the conductive particles.

Embodiment 21 provides the method of any one of embodiments 1-20, wherein the conductive particles have a discharge capacity of about 120 mAh/g to about 170 mAh/g.

Embodiment 22 provides the method of any one of embodiments 1-21, wherein the dispersion comprises 0.01 vol % to about 10 vol % of the conductive particles.

Embodiment 23 provides the method of any one of embodiments 1-22, wherein the conductive particles have a BET surface area of about 0.5 m²/g to about 25 m²/g.

Embodiment 24 provides the method of any one of embodiments 1-23, further comprising aging the dispersion for about 1 minute to about 30 days to provide an aged dispersion; and detecting a change in the resistance of the aged dispersion compared to an identical dispersion that is not aged.

Embodiment 25 provides the method of any one of embodiments 1-24, wherein the particles are mechanically perturbed during the measuring.

Embodiment 26 provides a method of characterizing a dispersion, comprising: electrically applying an excitation signal to the dispersion; and measuring an electrical response elicited by the excitation signal; wherein the dispersion comprises conductive particles of a lithium-ion conducting material and an aqueous electrolyte; and wherein the particles are mechanically perturbed by flowing the dispersion including the particles through an electrochemical cell comprising a channel.

Embodiment 27 provides the method claim 26, wherein the lithium-ion conducting material is LFP or LTO.

Embodiment 28 provides the method of any one of embodiments 26-27, wherein the aqueous electrolyte is Li₂SO₄.

Embodiment 29 provides a system for characterizing a dispersion, comprising: an anode; a cathode; an electrolyte; and a dispersion comprising conductive particles and a liquid carrier.

Embodiment 30 provides the system of embodiment 29, wherein the cathode comprises aluminum.

Embodiment 31 provides the system of any one of embodiments 29-30, wherein the anode comprises lithium.

Embodiment 32 provides the system of any one of embodiments 29-31, wherein the liquid carrier comprises an organic electrolyte.

Embodiment 33 provides the system of any one of embodiments 29-32, wherein the cathode comprises gold.

Embodiment 34 provides the system of any one of embodiments 29-33, wherein the anode comprises platinum.

Embodiment 35 provides the system of any one of embodiments 29-34, wherein at least one of the anode or the cathode has a serpentine shape.

Embodiment 36 provides the system of any one of embodiments 29-35, wherein the liquid carrier is an aqueous electrolyte.

Embodiment 37 provides the system of any one of embodiments 29-36, wherein at least 80% of the electrical resistance in the system is due to the conductive particles.

Embodiment 38 provides the system of any one of embodiments 29-37, wherein the conductive particles themselves undergo an electrochemical reaction.

Embodiment 39 provides the system of any one of embodiments 29-38, wherein the system further comprises a fluid inlet and a fluid outlet.

Embodiment 40 provides the system of any one of embodiments 29-39, wherein the dispersion including the conductive particles flows through the fluid inlet and fluid outlet.

Embodiment 41 provides the system of any one of embodiments 29-40, wherein the conductive particles are mechanically perturbed as they flow through the fluid inlet and fluid outlet.

Embodiment 42 provides the system of any one of embodiments 29-41, wherein the system further comprises a permeable separator between the anode and the cathode.

Embodiment 43 provides the system of any one of embodiments 29-42, wherein the anode and the cathode are disposed between two non-conductive polymer surfaces.

Embodiment 44 provides the system of any one of embodiments 29-43, wherein the polymer comprises polypropylene.

What is claimed is:

1. A method of characterizing a dispersion, comprising:
electrically applying an excitation signal to the dispersion; and
measuring an electrical response elicited by the excitation signal;
wherein the dispersion comprises electrically conductive particles and a liquid carrier; and
wherein the particles are mechanically perturbed.

2. The method of claim 1, wherein the excitation comprises a specified voltage applied to the dispersion and wherein the electrical response comprises a measured current.

3. The method of claim 1, wherein the excitation comprises a specified current applied to the dispersion and wherein the electrical response comprises a measured voltage.

4. The method of claim 1, wherein perturbing the particles comprises agitating the particles in a vessel.

5. The method of claim 1, wherein perturbing the particles comprises flowing the dispersion including the particles through an electrochemical cell comprising a channel.

6. The method of claim 5, wherein the electrochemical cell comprises:
an anode;
a cathode;
a permeable membrane between the anode and cathode; and
a fluid inlet and a fluid outlet.

7. The method of claim 1, wherein perturbing the particles comprises stirring the dispersion including the particles in an electrochemical cell.

8. The method of claim 5, wherein the electrochemical cell comprises:
an anode;
a cathode; and
a stir bar.

9. The method of claim 1, wherein the liquid carrier comprises an electrolyte.

10. The method of claim 1, wherein the electrolyte is an aqueous electrolyte or an organic electrolyte.

11. The method of claim 1, wherein the conductive particles comprise an alkali metal ion conducting material.

12. The method of claim 11, wherein the alkali metal ion conducting material is a lithium-ion conducting material, a sodium-ion conducting material, or mixtures thereof.

13. The method of claim 12, wherein the lithium-ion conducting material comprises LiFePO₄ (LFP), Li₄Ti₅O₁₂ (LTO), LiFeMnPO₄, LiCoO₂, LiMn₂O₄, LiNiMnCoO₂ (NMC), LiNiCoAlO₂, or mixtures thereof.

14. The method of claim 13, wherein the lithium-ion conducting material is LFP or LTO.

15. The method of claim 1, wherein at least 80% of the electrical resistance is due to the conductive particles.

16. The method of claim 1, further comprising:
aging the dispersion for about 1 minute to about 30 days to provide an aged dispersion; and
detecting a change in the resistance of the aged dispersion compared to an identical dispersion that is not aged.

17. A method of characterizing a dispersion, comprising:
electrically applying an excitation signal to the dispersion; and
measuring an electrical response elicited by the excitation signal;
wherein the dispersion comprises electrically conductive particles of a lithium-ion conducting material and an aqueous electrolyte; and
wherein the particles are mechanically perturbed by flowing the dispersion including the particles through an electrochemical cell comprising a channel.

18. The method claim 17, wherein the lithium-ion conducting material is LFP or LTO.

19. A system for characterizing a dispersion, comprising:
an anode;
a cathode;
an electrolyte; and
a dispersion comprising electrically conductive particles and a liquid carrier.

20. The system of claim 19, wherein at least 90% of the electrical resistance in the system is due to the conductive particles.
